(19) United States
(12) Patent Application Publication
(10) Pub. No.: US 2026/0143713 A1
(43) Pub. Date: May 21, 2026

(54) THREE-DIMENSIONAL SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventor: Ki Joon KIM, Suwon-si (KR)

(73) Assignee: SAMSUNG ELECTRONICS CO., LTD., Suwon-si (KR)

(21) Appl. No.: 19/205,213

(22) Filed: May 12, 2025

(30) Foreign Application Priority Data
Nov. 15, 2024 (KR) 10-2024-0163462

(51) Int. Cl. H10B 51/20; H10B 51/10; H10B 51/30; H10D 30/01; H10D 30/69; H10D 64/01; H10D 64/68

(52) U.S. Cl. CPC H10B 51/20; H10B 51/10; H10B 51/30; H10D 30/701; H10D 64/689; H10D 30/0415; H10D 64/033

(57) ABSTRACT

A three-dimensional semiconductor memory device includes a stack on a first structure, the stack comprising gate electrodes and insulating layers, which are alternately stacked in a first direction perpendicular to a top surface of the first structure; and a second structure extended in the first direction to penetrate the stack, in which the second structure includes: a semiconductor pattern extended in the first direction to penetrate the stack; and a data storage pattern between the stack and the semiconductor pattern, in which the data storage pattern comprises a ferroelectric pattern, in which the ferroelectric pattern comprises a first pattern and a second pattern in which the first pattern has a first dielectric constant and the second pattern has a second dielectric constant different from the first dielectric constant, and in which an effective dielectric constant of the ferroelectric pattern ranges from 1 to 15.

### CROSS-REFERENCE TO RELATED APPLICATIONS

This U.S. non-provisional patent application claims priority under 35 U.S.C. § 119 to Korean Patent Application No. 10-2024-0163462, filed on Nov. 15, 2024, in the Korean Intellectual Property Office, the entire contents of which are hereby incorporated by reference.

### BACKGROUND

### 1. Field

The present disclosure relates to a three-dimensional semiconductor memory device, and in particular, to a three-dimensional semiconductor memory device including a ferroelectric material, a method of fabricating the same, and an electronic system including the same.

### 2. Description of Related Art

Semiconductor memory devices are generally classified into volatile memory devices and nonvolatile memory devices. The volatile memory devices lose their stored data when their power supplies are interrupted. Examples of volatile memory devices include a dynamic random access memory (DRAM) device and a static random access memory (SRAM) device. The nonvolatile memory devices maintain their stored data even when their power supplies are interrupted. Examples of nonvolatile memory devices include a programmable read only memory (PROM), an erasable PROM (EPROM), an electrically-erasable PROM (EEPROM), a FLASH memory device. In addition, to meet an increasing demand for a semiconductor memory device with high performance and low power consumption, next-generation nonvolatile semiconductor memory devices, such as magnetic random access memory (MRAM), phase-change random access memory (PRAM), and ferroelectric random access memory (FeRAM) devices, are being developed. Various studies are being conducted to increase the integration density and performance of the next-generation semiconductor memory devices. For example, three-dimensional semiconductor memory devices, in which memory cells are three-dimensionally arranged, have been proposed. In a three-dimensional semiconductor memory device including a ferroelectric field effect transistor (FeFET), a ferroelectric pattern may include a ferroelectric material (e.g., hafnium oxide) having a relatively high dielectric constant (k=20-60). In this case, since a capacitance between a word line and a channel layer is relatively high, it takes a long time to perform reading and writing operations.

### SUMMARY

One or more embodiments of the present disclosure provides a three-dimensional semiconductor memory device including ferroelectric field effect transistors with improved electrical and operational characteristics and an electronic system including the same.

An embodiment of the present disclosure provides a three-dimensional semiconductor memory device, which is configured to easily increase an integration density of the ferroelectric field effect transistors therein, and an electronic system including the same.

According to an aspect of the disclosure, a three-dimensional semiconductor memory device includes a stack on a first structure, the stack comprising gate electrodes and insulating layers, which are alternately stacked in a first direction perpendicular to a top surface of the first structure; and a second structure extended in the first direction to penetrate the stack, in which the second structure includes: a semiconductor pattern extended in the first direction to penetrate the stack; and a data storage pattern between the stack and the semiconductor pattern, in which the data storage pattern comprises a ferroelectric pattern, in which the ferroelectric pattern comprises a first pattern and a second pattern in which the first pattern has a first dielectric constant and the second pattern has a second dielectric constant different from the first dielectric constant, and in which an effective dielectric constant of the ferroelectric pattern ranges from 1 to 15.

According to an aspect of the disclosure, a three-dimensional (3D) semiconductor memory device includes a stack on a first structure, the stack comprising gate electrodes and insulating layers, which are alternately stacked in a first direction perpendicular to a top surface of the first structure; a semiconductor pattern extended in the first direction to penetrate the stack; and a data storage pattern between the stack and the semiconductor pattern, in which the data storage pattern comprises a ferroelectric pattern, and in which an effective dielectric constant of the ferroelectric pattern ranges from 1 to 15.

### BRIEF DESCRIPTION OF THE DRAWINGS

FIG. 1 is a diagram schematically illustrating an electronic system including a three-dimensional semiconductor memory device according to one or more embodiments of the present disclosure.

FIG. 2 is a perspective view schematically illustrating an electronic system including a three-dimensional semiconductor memory device according to one or more embodiments of the present disclosure.

FIGS. 3 and 4 are sectional views, each of which is taken along a line I-I′ of FIG. 2 to illustrate a semiconductor package including a three-dimensional semiconductor memory device according to one or more embodiments of the present disclosure.

FIG. 5 is a plan view of a three-dimensional semiconductor memory device according to one or more embodiments of the present disclosure.

FIG. 6 is a sectional view taken along a line A-A′ of FIG. 5.

FIGS. 7 to 16 are enlarged sectional views illustrating a portion (e.g., P1 of FIG. 6) of a three-dimensional semiconductor memory device according to one or more embodiments of the present disclosure.

FIGS. 17 to 20 are sectional views corresponding to the line A-A′ of FIG. 5 and illustrating a method of fabricating a three-dimensional semiconductor memory device according to one or more embodiments of the present disclosure.

FIG. 21 is a sectional view taken along the line A-A′ of FIG. 5 to illustrate a three-dimensional semiconductor memory device according to one or more embodiments of the present disclosure.

FIGS. 22 to 31 are enlarged sectional views illustrating a portion (e.g., P2 of FIG. 21) of a three-dimensional semiconductor memory device according to one or more embodiments of the present disclosure.

FIGS. 32 to 34 are sectional views corresponding to the line A-A′ of FIG. 5 and illustrating a method of fabricating a three-dimensional semiconductor memory device according to one or more embodiments of the present disclosure.

FIG. 35 is a sectional view, which is taken along the line A-A′ of FIG. 5 to illustrate a three-dimensional semiconductor memory device according to one or more embodiments of the present disclosure.

FIGS. 36 and 37 are enlarged sectional views illustrating a portion (e.g., P3 of FIG. 35) of a three-dimensional semiconductor memory device according to one or more embodiments of the present disclosure.

FIG. 38 is a sectional view corresponding the line A-A′ of FIG. 5 and illustrating a method of fabricating a three-dimensional semiconductor memory device, according to one or more embodiments of the present disclosure.

FIG. 39 is a sectional view taken along the line A-A′ of FIG. 5 to illustrate a three-dimensional semiconductor memory device according to one or more embodiments of the present disclosure.

### DETAILED DESCRIPTION

Example embodiments of the present disclosures will now be described more fully with reference to the accompanying drawings, in which example embodiments are shown.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

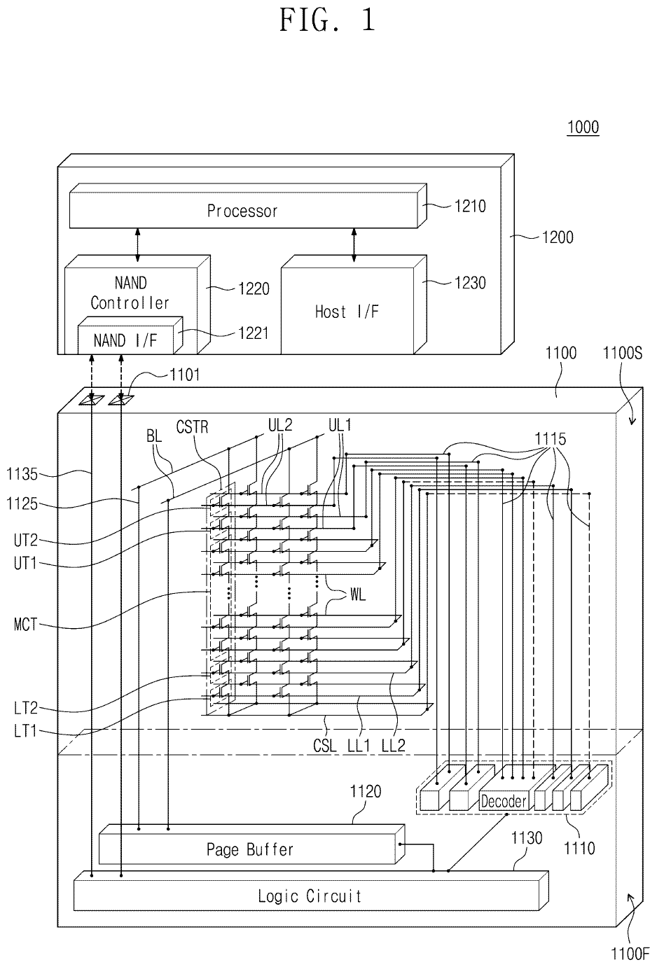

FIG. 1 is a diagram schematically illustrating an electronic system including a three-dimensional semiconductor memory device according to one or more embodiments of the present disclosure.

Referring to FIG. 1, an electronic system 1000 according to one or more embodiments of the present disclosure may include a three-dimensional semiconductor memory device 1100 and a controller 1200, which is electrically connected to the three-dimensional semiconductor memory device 1100. The electronic system 1000 may be a storage device including the three-dimensional semiconductor memory device 1100 or an electronic device including a storage device. For example, the electronic system 1000 may be a solid state drive (SSD) device, a universal serial bus (USB), a computing system, a medical system, or a communication system, in which the three-dimensional semiconductor memory device 1100 is provided. In one or more embodiments, a plurality of three-dimensional semiconductor memory devices 1100 may be provided.

The three-dimensional semiconductor memory device 1100 may be a nonvolatile memory device (e.g., a NAND FLASH memory device). The three-dimensional semiconductor memory device 1100 may include a first structure 1100F and a second structure 1100S on the first structure 1100F. In one or more examples, the first structure 1100F may be disposed beside the second structure 1100S.

The first structure 1100F may be a peripheral circuit structure, which includes a decoder circuit 1110, a page buffer 1120, and a logic circuit 1130. The second structure 1100S may be a memory cell structure including bit lines BL, a common source line CSL, word lines WL, first and second gate upper lines UL1 and UL2, first and second gate lower lines LL1 and LL2, and memory cell strings CSTR between the bit lines BL and the common source line CSL. In one or more examples, a memory cell string may refer to a series of connected NAND cells where a source of one cell is connected to a drain of a next cell.

In the second structure 1100S, each of the memory cell strings CSTR may include lower transistors LT1 and LT2 adjacent to the common source line CSL, upper transistors UT1 and UT2 adjacent to the bit lines BL, and a plurality of memory cell transistors MCT disposed between the lower transistors LT1 and LT2 and the upper transistors UT1 and UT2.

For example, each of the memory cell transistors MCT may include a data storing element containing a ferroelectric material. By using the data storing element with the ferroelectric material, it may be possible to realize a three-dimensional semiconductor memory device that can be operated with low power and with a fast operation speed. The word lines WL may be respectively used as gate electrodes of the memory cell transistors MCT. A voltage difference between the word lines WL and channel regions of the memory cell transistors MCT may be adjusted to cause a change in polarization of a dipole of the ferroelectric material, and this may be used to perform a data writing or erasing operation on the memory cell transistors MCT.

For example, the upper transistors UT1 and UT2 may include a string selection transistor, and the lower transistors LT1 and LT2 may include a ground selection transistor. The gate lower lines LL1 and LL2 may be the gate electrodes of the lower transistors LT1 and LT2, respectively. The gate upper lines UL1 and UL2 may be the gate electrodes of the upper transistors UT1 and UT2, respectively. The number of the lower transistors LT1 and LT2 and the number of the upper transistors UT1 and UT2 may be variously changed, according to embodiments.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F to the second structure 1100S. The bit lines BL may be electrically connected to the page buffer 1120 through second connection lines 1125, which are extended from the first structure 1100F to the second structure 1100S.

In the first structure 1100F, the decoder circuit 1110 and the page buffer 1120 may execute a control operation on at least one memory cell transistor that is selected from the memory cell transistors MCT. The decoder circuit 1110 and the page buffer 1120 may be controlled by the logic circuit 1130. The three-dimensional semiconductor memory device 1100 may communicate with the controller 1200 through an input/output pad 1101, which is electrically connected to the logic circuit 1130. The input/output pad 1101 may be electrically connected to the logic circuit 1130 through an input/output connection line 1135, which is extended from the first structure 1100F to the second structure 1100S.

The first structure 1100F may further include a voltage generator. The voltage generator may generate a program voltage, a read voltage, a pass voltage, a verify voltage, and so forth, which are needed to operate the memory cell strings CSTR. Here, the program voltage may be a relatively high-voltage (e.g., 20V to 40V), compared with the read voltage, the pass voltage, and the verify voltage.

The first structure 1100F may include a high-voltage transistors and a low-voltage transistors. The decoder circuit 1110 may include pass transistors which are connected to the word lines WL of the memory cell strings CSTR. The pass transistors may include high-voltage transistors which can stand a high voltage (e.g., the program voltage) applied to the word lines WL during a programming operation. The page buffer 1120 may also include high-voltage transistors that can stand a high voltage.

The controller 1200 may include a processor 1210, a NAND controller 1220, and a host interface 1230. In one or more embodiments, a plurality of three-dimensional semiconductor memory devices 1100 may be provided, and the controller 1200 may be configured to control the three-dimensional semiconductor memory devices 1100.

The processor 1210 may control overall operations of the electronic system 1000 including the controller 1200. Based on a specific firmware, the processor 1210 may execute operations of controlling the NAND controller 1220 and accessing the three-dimensional semiconductor memory device 1100. The NAND controller 1220 may include a NAND interface 1221, which is used for communication with the three-dimensional semiconductor memory device 1100. The NAND interface 1221 may be used to transmit and receive control commands, which will be used to control the three-dimensional semiconductor memory device 1100 and data, which will be written in or read from the memory cell transistors MCT. The host interface 1230 may be configured to allow for communication between the electronic system 1000 and an external host. If a control command is received from the external host through the host interface 1230, the processor 1210 may control the three-dimensional semiconductor memory device 1100 in response to the control command.

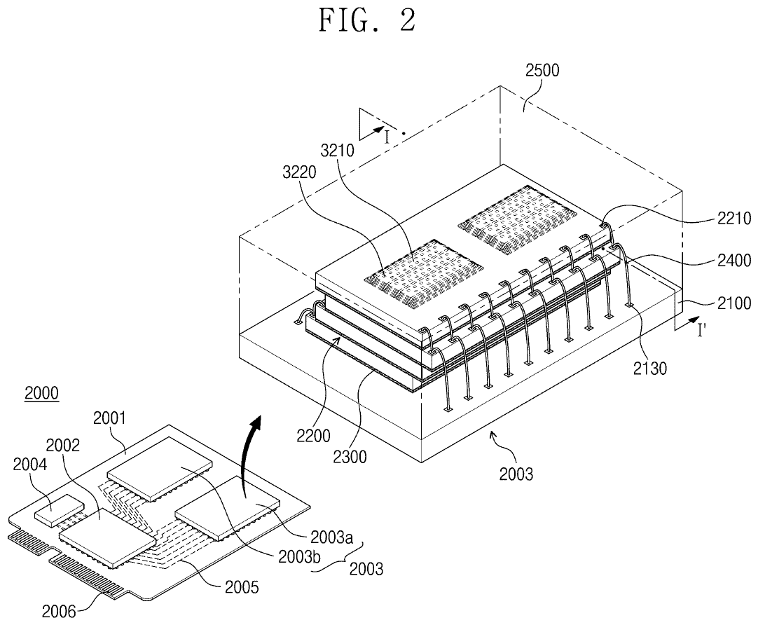

FIG. 2 is a perspective view schematically illustrating an electronic system including a three-dimensional semiconductor memory device according to one or more embodiments of the present disclosure.

Referring to FIG. 2, an electronic system 2000 according to one or more embodiments of the present disclosure may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 through interconnection patterns 2005, which are formed in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. In one or more embodiments, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In one or more embodiments, the electronic system 2000 may be driven by an electric power, which is supplied from the external host through the connector 2006. The electronic system 2000 may further include a power management integrated circuit (PMIC) that is used to separately supply the electric power, which is provided from the external host, to the controller 2002 and the semiconductor package 2003.

The controller 2002 may be configured to control a data-writing or data-reading operation on the semiconductor package 2003 and to improve an operation speed of the electronic system 2000.

The DRAM 2004 may be a buffer memory, which relieves technical difficulties caused by a difference in speed between the semiconductor package 2003, which serves as a data storage device, and the external host. In one or more embodiments, the DRAM 2004 in the electronic system 2000 may serve as a cache memory and may be used as a storage space, which is configured to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which may be spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 respectively disposed on bottom surfaces of the semiconductor chips 2200, a connection structure 2400 electrically connecting the semiconductor chips 2200 to the package substrate 2100, and a molding layer 2500 provided on the package substrate 2100 to cover the semiconductor chips 2200 and the connection structure 2400.

The package substrate 2100 may be a printed circuit board including upper pads 2130. Each of the semiconductor chips 2200 may include an input/output pad 2210. The input/output pad 2210 may correspond to the input/output pad 1101 of FIG. 1. Each of the semiconductor chips 2200 may include stacks 3210 and vertical structures 3220. Each of the semiconductor chips 2200 may include a three-dimensional semiconductor memory device to be described below.

The connection structure 2400 may be, for example, bonding wires electrically connecting the input/output pad 2210 to the upper pads 2130. Thus, in each of the first and second semiconductor packages 2003a and 2003b, the semiconductor chips 2200 may be electrically connected to each other using one or more bonding wires and may be electrically connected to the upper pads 2130 of the package substrate 2100. In one or more embodiments, the semiconductor chips 2200 in each of the first and second semiconductor packages 2003a and 2003b may be electrically connected to each other by a connection structure including through silicon vias (TSVs), not by the connection structure 2400 provided in the form of bonding wires.

In one or more embodiments, the controller 2002 and the semiconductor chips 2200 may be provided in a single package, but the present disclosure is not limited to this example. For example, the controller 2002 and the semiconductor chips 2200 may be mounted on an additional interposer substrate, which is prepared regardless of the main substrate 2001, and may be connected to each other through interconnection lines, which are provided in the interposer substrate. The embodiments are not limited to the configuration illustrated in FIG. 2. For example, the main substrate 2001 may include any desired number of substrates.

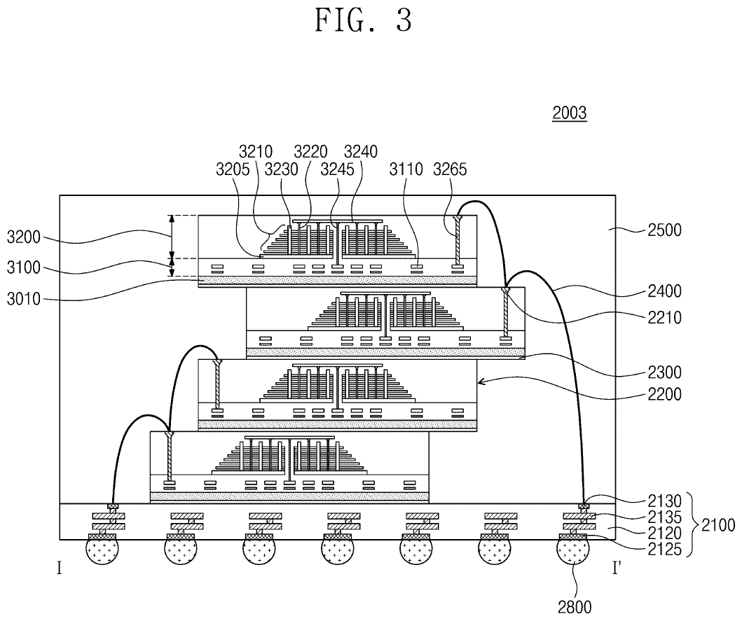

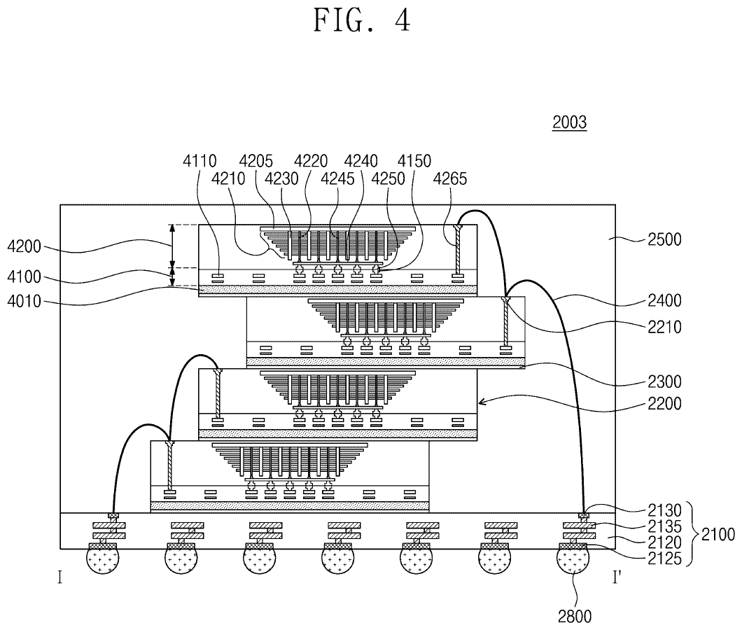

FIGS. 3 and 4 are sectional views, each of which is taken along a line I-I′ of FIG. 2 to illustrate a semiconductor package including a three-dimensional semiconductor memory device according to one or more embodiments of the present disclosure.

Referring to FIG. 3, the package substrate 2100 of the semiconductor package 2003 may be a printed circuit board. The package substrate 2100 may include a package substrate body portion 2120, upper pads 2130 disposed on a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005 of the main substrate 2001 of the electronic system 2000 through conductive connecting portions 2800, as shown in FIG. 2.

Each of the semiconductor chips 2200 may include a semiconductor substrate 3010 and a first structure 3100 and second structure 3200, which are sequentially stacked on the semiconductor substrate 3010. The first structure 3100 may include a peripheral circuit region, which includes peripheral lines 3110. The second structure 3200 may include a source structure 3205, a stack 3210 on the source structure 3205, vertical structures 3220 and separation structures 3230, which are provided to penetrate the stack 3210, bit lines 3240, which are electrically connected to the vertical structures 3220, and cell contact plugs 3235, which are electrically connected to the word lines WL (e.g., see FIG. 1) of the stack 3210.

Each of the semiconductor chips 2200 may include penetration lines 3245, which are electrically connected to the peripheral lines 3110 of the first structure 3100 and are extended into the second structure 3200. The penetration lines 3245 may be disposed outside the stack 3210 and may be provided to penetrate the stack 3210. Each of the semiconductor chips 2200 may further include an input/output pad 2210 electrically connected to the peripheral lines 3110 of the first structure 3100. In one or more examples, a structure may refer to a layer of a semiconductor package having one or more semiconductor components.

Referring to FIG. 4, each of the semiconductor chips 2200 of the semiconductor package 2003 may include a semiconductor substrate 4010, a first structure 4100, which is placed on the semiconductor substrate 4010, and a second structure 4200, which is placed on and bonded to the first structure 4100 in a wafer bonding manner.

The first structure 4100 may include a peripheral circuit region, in which a peripheral line 4110 and first junction structures 4150 are provided. The second structure 4200 may include a source structure 4205, a stack 4210, which is provided between the source structure 4205 and the first structure 4100, vertical structures 4220 and a separation structure 4230, which are provided to penetrate the stack 4210, and second junction structures 4250, which are electrically and respectively connected to the vertical structures 4220 and the word lines WL (e.g., see FIG. 1) of the stack 4210. For example, the second junction structures 4250 may be electrically connected to the vertical structures 4220 and the word lines WL (e.g., see FIG. 1) through bit lines 4240, which are electrically connected to the vertical structures 4220, and cell contact plugs 4235, which are electrically connected to the word lines WL of FIG. 1. The first junction structures 4150 of the first structure 4100 may be in contact with and bonded to the second junction structures 4250 of the second structure 4200. The first and second junction structures 4150 and 4250 may be formed of or include copper (Cu).

Referring to FIGS. 3 and 4, the first structure 3100 or 4100 and the second structure 3200 or 4200 may correspond to the first structure 1100F and the second structure 1100S, respectively, shown in FIG. 1. The semiconductor chips 2200 may be electrically connected to each other by the connection structures 2400, which are provided in the form of bonding wires, but the present disclosure is not limited to this example. In one or more examples, the semiconductor chips 2200 may be electrically connected to each other by penetration electrodes penetrating the semiconductor chips 2200.

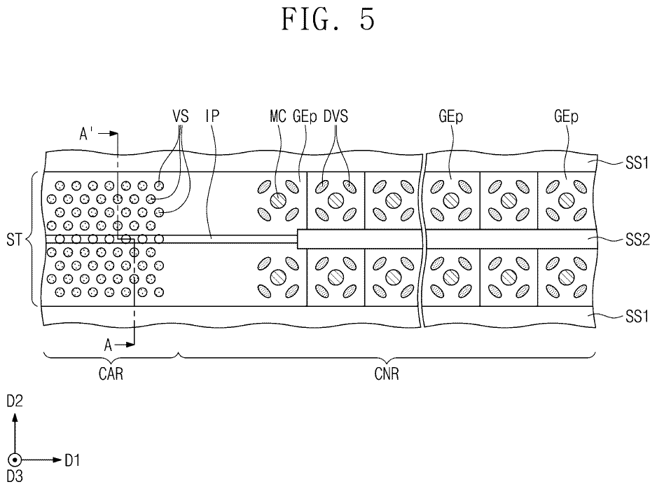

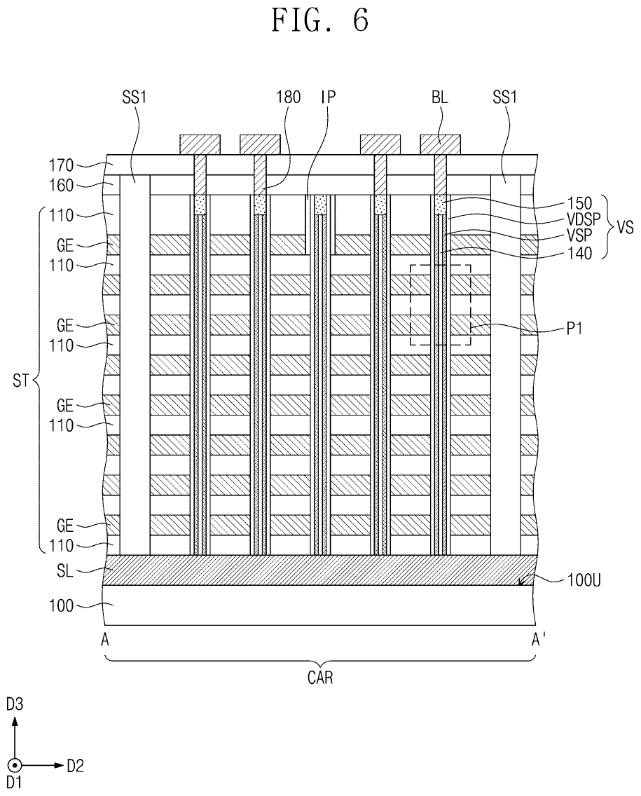

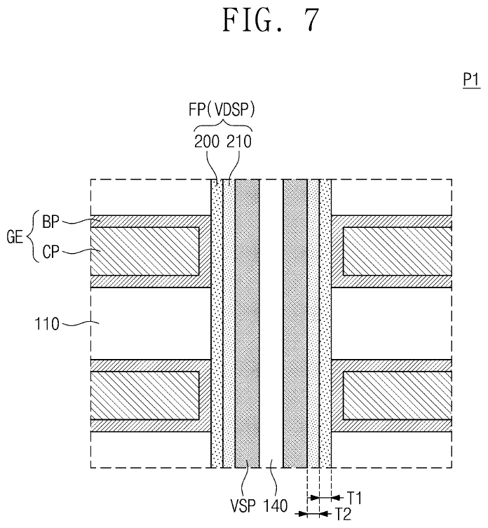

FIG. 5 is a plan view of a three-dimensional semiconductor memory device according to one or more embodiments of the present disclosure. FIG. 6 is a sectional view taken along a line A-A′ of FIG. 5, and FIG. 7 is an enlarged sectional view illustrating a portion P1 of FIG. 6.

Referring to FIGS. 5 and 6, a source line SL may be disposed on a lower structure 100. The lower structure 100 may include a semiconductor substrate and a lower insulating layer on the semiconductor substrate. In one or more embodiments, the semiconductor substrate may include a silicon substrate, a silicon-germanium substrate, a germanium substrate, or a single-crystalline epitaxial layer grown from a single-crystalline silicon substrate. The lower insulating layer may include a silicon oxide layer, a silicon nitride layer, a silicon oxynitride layer, and/or a low-k dielectric layer. The lower structure 100 may include a cell array region CAR and a connection region CNR.

The source line SL may be disposed on the cell array region CAR of the lower structure 100. In one or more embodiments, the source line SL may be a plate-shaped pattern that is extended in a first direction D1 and a second direction D2, which are parallel to a top surface 100U of the lower structure 100 and cross(or, are not parallel) to each other. The source line SL may be extended to a region on the connection region CNR of the lower structure 100 in the first direction D1, but the present disclosure is not limited to this example. The source line SL may include a conductive material. The source line SL may correspond to the common source line CSL of FIG. 1.

A stack ST may be disposed on the source line SL. The stack ST may be disposed on the cell array region CAR of the lower structure 100 and may be extended in the first direction D1 onto the connection region CNR of the lower structure 100. The source line SL may be interposed between the lower structure 100 and the stack ST.

First separation structures SS1 may be disposed on the source line SL and may be spaced apart from each other, in the second direction D2, with the stack ST interposed therebetween. The first separation structures SS1 may be disposed on the cell array region CAR of the lower structure 100 and may be extended onto the connection region CNR of the lower structure 100 in the first direction D1. The source line SL may be extended into a region between each of the first separation structures SS1 and the lower structure 100. The first separation structures SS1 may be respectively disposed on side surfaces of the stack ST, which are opposite to each other in the second direction D2, and may include an insulating material. In one or more examples, the insulating material may server the function such that regions of a semiconductor device between the separation structures are isolated from each other. The first separation structures SS1 may be formed of or include at least one of, for example, silicon oxide, silicon nitride, silicon oxynitride, low-k dielectric materials, high density plasma (HDP) oxide, and/or Tetraethyl Orthosilicate (TEOS). In one or more examples, each separation structure may be spaced apart from each other in D2 direction by an equal amount. In one or more examples, two separation structures may be spaced apart from each other in the direction D2 by an amount that is different from the other separation structure.

The stack ST may include gate electrodes GE and insulating layers 110, which are alternately stacked in a third direction D3 perpendicular to the top surface 100U of the lower structure 100. The third direction D3 may be referred to as a vertical direction. The lowermost one of the insulating layers 110 may be disposed between the lowermost one of the gate electrodes GE and the source line SL. The uppermost one of the insulating layers 110 may be disposed on the uppermost one of the gate electrodes GE. The gate electrodes GE and the insulating layers 110 may be stacked on the cell array region CAR of the lower structure 100 in the third direction D3 and may be extended onto the connection region CNR of the lower structure 100 in the first direction D1. The gate electrodes GE may include pad portions GEp disposed on the connection region CNR. The pad portions GEp of the gate electrodes GE may be disposed at positions, which are different from each other in horizontal and vertical directions, and may form a stepwise structure on the connection region CNR. Thus, the stack ST may have a stepwise structure on the connection region CNR. The gate electrodes GE may correspond to the word lines WL, the first and second gate upper lines UL1 and UL2, and the first and second gate lower lines LL1 and LL2 of FIG. 1.

Each of the gate electrodes GE and the insulating layers 110 may have a thickness in the third direction D3. In one or more embodiments, the gate electrodes GE may be provided to have substantially the same thickness. In one or more examples, each gate electrode GE may have the same thickness. In one or more examples, two gate electrodes GE may have a different thickness from each other. A thickness of the uppermost one of the insulating layers 110 may be larger than a thickness of each of the remaining ones of the insulating layers 110. The remaining ones of the insulating layers 110 may be provided to have substantially the same thickness. Each of the gate electrodes GE may have a length in the first direction D1. The lengths of the gate electrodes GE may decrease as a distance from the lower structure 100 in the third direction D3 increases. As an example, the uppermost one of the gate electrodes GE may have the smallest length, and the lowermost one of the gate electrodes GE may have the largest length. Each of the insulating layers 110 may have a length in the first direction D1. Lengths of the insulating layers 110 may decrease as a distance from the lower structure 100 in the third direction D3 increases. As an example, the uppermost one of the insulating layers 110 may have the smallest length, and the lowermost one of the insulating layers 110 may have the largest length.

The gate electrodes GE may be formed of or include at least one of, for example, doped semiconductor materials (e.g., doped silicon), metallic materials (e.g., tungsten, copper, and aluminum), conductive metal nitride materials (e.g., titanium nitride and tantalum nitride), or transition metals (e.g., titanium and tantalum). The insulating layers 110 may be formed of or include at least one of, for example, silicon oxide, silicon nitride, silicon oxynitride, low-k dielectric materials, high density plasma (HDP) oxide, and/or Tetraethyl Orthosilicate (TEOS).

A separation insulating pattern IP may be disposed on the cell array region CAR of the lower structure 100 and may penetrate an upper portion of the stack ST in the third direction D3. The separation insulating pattern IP may be provided to penetrate at least the uppermost insulating layer 110 and the uppermost gate electrode GE. The separation insulating pattern IP may be extended in the first direction D1, between the first separation structures SS1. The separation insulating pattern IP may be extended onto the connection region CNR of the lower structure 100 in the first direction D1. Thus, the uppermost gate electrode GE may be divided into pair of uppermost gate electrodes GE, which are spaced apart from each other in the second direction D2 by the separation insulating pattern IP. For example, the separation insulating pattern IP may isolate two groups of gate electrodes GE from each other. The separation insulating pattern IP may include at least one of insulating materials (e.g., silicon oxide, silicon nitride, silicon oxynitride, low-k dielectric materials, high density plasma (HDP) oxide, and/or Tetraethyl Orthosilicate (TEOS)).

A second separation structure SS2 may be disposed on the connection region CNR of the lower structure 100 to penetrate the stack ST in the third direction D3. The second separation structure SS2 may be provided on the connection region CNR to penetrate the pad portions GEp of the gate electrodes GE and the insulating layers 110. The second separation structure SS2 may be extended in the first direction D1, between the first separation structures SS1, and may be connected to the separation insulating pattern IP. The second separation structure SS2 may include at least one of insulating materials (e.g., silicon oxide, silicon nitride, silicon oxynitride, low-k dielectric materials, high density plasma (HDP) oxide, and/or Tetraethyl Orthosilicate (TEOS)).

Vertical structures VS may be disposed on the cell array region CAR of the lower structure 100 to penetrate the stack ST in the third direction D3. The vertical structures VS may be spaced apart from each other in the first and second directions D1 and D2 and may be arranged to form a zigzag shape in the first or second direction D1 or D2. The vertical structures VS may be electrically connected to the source line SL. Each of the vertical structures VS may constitute the memory cell string CSTR of FIG. 1.

Each of the vertical structures VS may include a vertical semiconductor pattern VSP, which is extended in the third direction D3 to penetrate the stack ST. A bottom end of the vertical semiconductor pattern VSP may be electrically connected to the source line SL. In one or more embodiments, the vertical semiconductor pattern VSP may have a hollow cylinder shape with an empty region, and each of the vertical structures VS may further include a gapfill insulating pattern 140 filling the empty region of the vertical semiconductor pattern VSP. The gapfill insulating pattern 140 may be a pillar-shaped pattern extending in the third direction D3, and the vertical semiconductor pattern VSP may be provided to enclose a side surface of the gapfill insulating pattern 140.

Each of the vertical structures VS may further include a vertical data storage pattern VDSP between the vertical semiconductor pattern VSP and the stack ST. In one or more embodiments, the vertical data storage pattern VDSP may be extended in the third direction D3 to penetrate the stack ST. The vertical data storage pattern VDSP may be extended in the third direction D3 to penetrate the gate electrodes GE and the insulating layers 110. The vertical data storage pattern VDSP may enclose a side surface of the vertical semiconductor pattern VSP. The vertical data storage pattern VDSP may be referred to as a data storage pattern.

Each of the vertical structures VS may further include a conductive pad 150 connected to an upper portion of the vertical semiconductor pattern VSP. The conductive pad 150 may be disposed on the vertical semiconductor pattern VSP and the gapfill insulating pattern 140. The vertical data storage pattern VDSP may be extended onto a side surface of the conductive pad 150 to enclose the side surface of the conductive pad 150, but the present disclosure is not limited to this example.

The vertical semiconductor pattern VSP may be formed of or include at least one of semiconductor materials (e.g., doped Si, poly-Si, and SiGe), semiconductor oxide materials (e.g., IGZO, Sn-IGZO, IWO, CuS₂, CuSe₂, WSe₂, IZO, ZTO, and YZO), or two-dimensional semiconductor materials (e.g., MoS₂, MoSe₂, and WS₂). The vertical semiconductor pattern VSP may be used as the channel regions of the upper transistors UT1 and UT2, the memory cell transistors MCT, and the lower transistors LT1 and LT2 of FIG. 1. The gapfill insulating pattern 140 may include at least one of insulating materials (e.g., silicon oxide, silicon nitride, silicon oxynitride, low-k dielectric materials, high density plasma (HDP) oxide, and/or Tetraethyl Orthosilicate (TEOS)). The conductive pad 150 may include at least one of conductive materials or doped semiconductor materials (e.g., doped silicon).

Referring to FIGS. 6 and 7, the vertical data storage pattern VDSP may include a ferroelectric pattern FP. In one or more embodiments, the ferroelectric pattern FP may be interposed between each of the gate electrodes GE and the vertical semiconductor pattern VSP and may be extended into a region between each of the insulating layers 110 and the vertical semiconductor pattern VSP.

The ferroelectric pattern FP may have an effective dielectric constant (ϵ_{eff}) ranging from 1 to 15. In one or more examples, the effective dielectric constant may be a value that corresponds to the dielectric properties of an area. The effective dielectric constant may be dependent on the dimensions, frequency, and/or substrate properties of the area. The effective dielectric constant may be a function of a ratio of a width to a height of the area, as well as the dielectric constant of the substrate material in the area. The ferroelectric pattern FP may be formed of or include at least one of doped aluminum nitride, doped zinc oxide, two-dimensional ferroelectric materials, or a laminated structure, in which ferroelectric layers and low-k dielectric layers are stacked. The doped aluminum nitride may include aluminum nitride doped with at least one of Sc, B, Y, and La and may include, for example, Sc-doped AlN, B-doped AlN, Y-doped AlN, or La-doped AlN. The doped zinc oxide may include, for example, Mg-doped ZnO. The two-dimensional ferroelectric material may include, for example, amorphous In₂Se₃. The ferroelectric layer of the laminated structure may include HfO₂, HfSiO₂ (Si-doped HfO₂), HfAlO₂ (Al-doped HfO₂), HfSiON, HfZnO, HfZrO₂, ZrO₂, ZrSiO₂, HfZrSiO₂, ZrSiON, LaAlO, HfDyO₂, or HfScO₂. The low-k dielectric layer of the laminated structure may include at least one of aluminum oxide, silicon oxide, or materials having dielectric constants lower than silicon oxide.

In one or more embodiments, the ferroelectric pattern FP may include a first pattern 200 and a second pattern 210 having different dielectric constants from each other. The first pattern 200 may be interposed between the stack ST and the vertical semiconductor pattern VSP, and the second pattern 210 may be interposed between the first pattern 200 and the vertical semiconductor pattern VSP. The first and second patterns 200 and 210 may be interposed between each of the gate electrodes GE and the vertical semiconductor pattern VSP and may be extended into a region between each of the insulating layers 110 and the vertical semiconductor pattern VSP.

In one or more embodiments, the second pattern 210 may include a material having a dielectric constant lower than the first pattern 200. For example, the dielectric constant of the second pattern 210 may be lower than the dielectric constant of the first pattern 200. The second pattern 210 may include a material having a crystallization temperature higher than the first pattern 200. The second pattern 210 may have an amorphous structure. In one or more examples, a pattern with an amorphous structure may refer to a pattern that has no organization (e.g., non-crystalline structure). The second pattern 210 may include a material having a band gap energy greater than the first pattern 200. In one or more examples, a band gap energy between two materials may refer to an energy difference between valence and conduction bands of the materials. By contrast, in another embodiment, the first pattern 200 may include a material having a dielectric constant lower than the second pattern 210. For example, the dielectric constant of the first pattern 200 may be lower than the dielectric constant of the second pattern 210. The first pattern 200 may include a material having a crystallization temperature higher than the second pattern 210. In one or more examples, the crystallization temperature may refer to a temperature at which a material transitions from a liquid or an amorphous state to a crystalline state. The first pattern 200 may have an amorphous structure. The first pattern 200 may include a material having a band gap energy greater than the second pattern 210.

In one or more embodiments, each of the first and second patterns 200 and 210 may include at least one of doped aluminum nitride, doped zinc oxide, two-dimensional ferroelectric materials, or a laminated structure, in which ferroelectric layers and low-k dielectric layers are stacked. In another embodiment, one of the first and second patterns 200 and 210 may include a ferroelectric material, and the other of the first and second patterns 200 and 210 may include an anti-ferroelectric material or a low-k dielectric material. The ferroelectric material may include HfO₂, HfSiO₂ (Si-doped HfO₂), HfAlO₂ (Al-doped HfO₂), HfSiON, HfZnO, HfZrO₂, ZrO₂, ZrSiO₂, HfZrSiO₂, ZrSiON, LaAlO, HfDyO₂, or HfScO₂. The anti-ferroelectric material may include at least one of ZrO₂ or HfZrO₂. The low-k dielectric material may include at least one of aluminum oxide, silicon oxide, or materials having dielectric constants lower than silicon oxide.

Each of the first and second patterns 200 and 210 may have a thickness in a direction (e.g., the second direction D2) parallel to the top surface 100U of the lower structure 100. A thickness T1 of the first pattern 200 may range from 0.1 nm to 15 nm, and a thickness T2 of the second pattern 210 may range from 0.1 nm to 15 nm. A sum of the thicknesses T1 and T2 of the first and second patterns 200 and 210 or a thickness of the ferroelectric pattern FP (i.e., T1+T2) may be smaller than or equal to 20 nm. In one or more examples, when the first pattern 200 and the second pattern 210 have different dielectric constants, a first dielectric constant ϵ1 and a first thickness T1 may be determined for the first pattern 200, a second dielectric constant ϵ2 and a second thickness T2 may be determined for the second pattern 210, and an effective dielectric constant (ϵ_{eff}) for the ferroelectric pattern FP may be obtained as follows, ϵ_{eff}=(T1+T2)/(ϵ1/T1+ϵ2/T2).

In one or more embodiments, each of the gate electrodes GE may include a conductive pattern CP and a barrier pattern BP. The barrier pattern BP may be interposed between the conductive pattern CP and the insulating layers 110 adjacent thereto and may be extended into a region between the conductive pattern CP and the vertical data storage pattern VDSP. The conductive pattern CP may include at least one of metallic materials, and the barrier pattern BP may include at least one of conductive metal nitride materials.

Referring back to FIGS. 5 and 6, a vertical dummy structures DVS may be disposed on the connection region CNR of the lower structure 100 and may be extended in the third direction D3 to penetrate the stack ST. The vertical dummy structures DVS may be provided to penetrate the pad portions GEp of the gate electrodes GE. The vertical dummy structures DVS may have the same thin film structure as the vertical structures VS.

Cell contact plugs MC may be disposed on the connection region CNR of the lower structure 100 and on the stack ST. The cell contact plugs MC may be disposed on and electrically connected to the pad portions GEp of the gate electrodes GE, respectively. The vertical dummy structures DVS may be disposed to enclose the cell contact plugs MC, respectively, when viewed in a plan view. The cell contact plugs MC may include at least one of conductive materials (e.g., metallic materials).

A planarization insulating layer 160 may be disposed on the cell array region CAR and the connection region CNR of the lower structure 100 and on the stack ST. The planarization insulating layer 160 may cover top surfaces of the stack ST and the vertical structures VS on the cell array region CAR and may cover the stepwise structure of the stack ST on the connection region CNR. The planarization insulating layer 160 may include a silicon oxide layer, a silicon nitride layer, a silicon oxynitride layer, and/or a low-k dielectric layer. The first and second separation structures SS1 and SS2 may penetrate the planarization insulating layer 160 in the third direction D3.

An upper insulating layer 170 may be disposed on the cell array region CAR and the connection region CNR of the lower structure 100 and on the planarization insulating layer 160. The upper insulating layer 170 may cover top surfaces of the first and second separation structures SS1 and SS2. The upper insulating layer 170 may include a silicon oxide layer, a silicon nitride layer, a silicon oxynitride layer, and/or a low-k dielectric layer.

Bit line contacts 180 may be disposed on the vertical structures VS, respectively. Each of the bit line contacts 180 may be disposed on the cell array region CAR of the lower structure 100 to penetrate the upper insulating layer 170 and the planarization insulating layer 160 and may be electrically connected to the conductive pad 150 of each of the vertical structures VS. Bit lines BL may be disposed on the upper insulating layer 170 and may be electrically connected to the bit line contacts 180. Each of the bit lines BL may be electrically connected to the conductive pads 150 and the vertical semiconductor patterns VSP of the vertical structures VS through a corresponding one of the bit line contacts 180. The bit lines BL may correspond to the bit lines BL of FIG. 1. The bit lines BL and the bit line contacts 180 may include a conductive material (e.g., a metallic material).

Since the vertical data storage pattern VDSP includes the ferroelectric pattern FP, the gate electrodes GE, the vertical data storage pattern VDSP, and the vertical semiconductor pattern VSP may constitute ferroelectric field effect transistors, which are used as the memory cells of the semiconductor device.

In the case where the vertical data storage pattern VDSP includes a ferroelectric material having a relatively high dielectric constant, a capacitance between the gate electrodes GE and the vertical semiconductor pattern VSP may be increased, and in this case, it may take a long time to perform the reading and writing operations on the memory cells.

According to one or more embodiments of the present disclosure, the ferroelectric pattern FP may have an effective dielectric constant ranging from 1 to 15, and thus, the capacitance between the gate electrodes GE and the vertical semiconductor pattern VSP may be reduced. Thus, it may be possible to improve operational characteristics in reading and writing operations on the memory cells composed of the ferroelectric field effect transistors. In addition, the ferroelectric field effect transistors may be stacked in a vertical direction (e.g., the third direction D3), and thus, it may be possible to easily increase an integration density of the ferroelectric field effect transistors provided in the semiconductor memory device.

Thus, it may be possible to improve electrical and operational characteristics of ferroelectric field effect transistors and to easily increase an integration density of a three-dimensional semiconductor memory device with the ferroelectric field effect transistors.

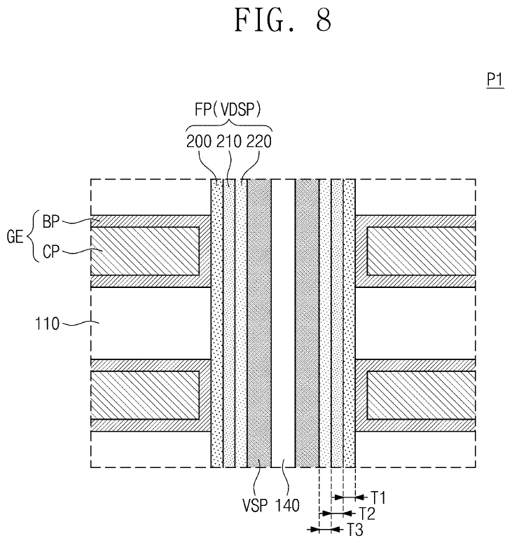

FIG. 8 is an enlarged view illustrating a portion (e.g., P1 of FIG. 6) of a three-dimensional semiconductor memory device according to one or more embodiments of the present disclosure. For the sake of brevity, features different from the three-dimensional semiconductor memory device described with reference to FIGS. 5 to 7 will be mainly described below.

Referring to FIGS. 6 and 8, the ferroelectric pattern FP may include a first pattern 200, a second pattern 210, and a third pattern 220, which are interposed between the stack ST and the vertical semiconductor pattern VSP. The first pattern 200 may be interposed between the stack ST and the vertical semiconductor pattern VSP, and the second pattern 210 may be interposed between the first pattern 200 and the vertical semiconductor pattern VSP. The third pattern 220 may be interposed between the second pattern 210 and the vertical semiconductor pattern VSP. The first to third patterns 200, 210, and 220 may be interposed between each of the gate electrodes GE and the vertical semiconductor pattern VSP and may be extended into a region between each of the insulating layers 110 and the vertical semiconductor pattern VSP.

The second pattern 210 may be formed of or include a material having a dielectric constant lower than the first and third patterns 200 and 220. For example, the dielectric constant of the second pattern 210 may be lower than the dielectric constant of the first pattern 200 and may be lower than the dielectric constant of the third pattern 220. The second pattern 210 may include a material having a higher crystallization temperature than the first and third patterns 200 and 220. The second pattern 210 may have an amorphous structure. The second pattern 210 may be formed of or include a material having a band gap energy greater than the first and third patterns 200 and 220. The dielectric constant of the third pattern 220 may be equal to or different from the dielectric constant of the first pattern 200.

In one or more embodiments, each of the first to third patterns 200, 210, and 220 may include at least one of doped aluminum nitride, doped zinc oxide, two-dimensional ferroelectric materials, or a laminated structure, in which ferroelectric layers and low-k dielectric layers are stacked. In another embodiment, the first and third patterns 200 and 220 may include a ferroelectric material, and the second pattern 210 may include an antiferroelectric material or a low-k dielectric material. The ferroelectric material may include HfO₂, HfSiO₂ (Si-doped HfO₂), HfAlO₂ (Al-doped HfO₂), HfSiON, HfZnO, HfZrO₂, ZrO₂, ZrSiO₂, HfZrSiO₂, ZrSiON, LaAlO, HfDyO₂, or HfScO₂. The anti-ferroelectric material may include at least one of ZrO₂ or HfZrO₂. The low-k dielectric material may include at least one of aluminum oxide, silicon oxide, or materials having dielectric constants lower than silicon oxide.

Each of the first to third patterns 200, 210, and 220 may have a thickness in a direction (e.g., the second direction D2) parallel to the top surface 100U of the lower structure 100. A thickness T1 of the first pattern 200 may range from 0.1 nm to 15 nm, and a thickness T2 of the second pattern 210 may range from 0.1 nm to 15 nm. A thickness T3 of the third pattern 220 may range from 0.1 nm to 15 nm. A sum of the thicknesses T1, T2, and T3 of the first, second, and third patterns 200, 210, and 220 or the thickness of the ferroelectric pattern FP (i.e., T1+T2+T3) may be smaller than or equal to 20 nm. In one or more examples, when the first pattern 200, second pattern 210, and third pattern 220 have different dielectric constants, a first dielectric constant ϵ1 and a first thickness T1 may be determined for the first pattern 200, a second dielectric constant ϵ2 and a second thickness T2 may be determined for the second pattern 210, a third dielectric constant ϵ3 and a third thickness T3 may be determined for the third pattern 220, and an effective dielectric constant (ϵ_{eff}) for the ferroelectric pattern FP may be obtained as follows, ϵ_{eff}=(T1+T2+T3)/(ϵ1/T1+ϵ2/T2+ϵ3/T3) .

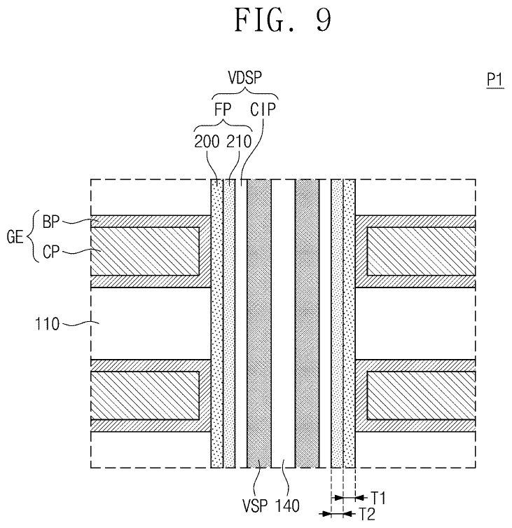

FIGS. 9 to 16 are enlarged sectional views illustrating a portion (e.g., P1 of FIG. 6) of a three-dimensional semiconductor memory device according to one or more embodiments of the present disclosure. For the sake of brevity, features different from the three-dimensional semiconductor memory device described with reference to FIGS. 5 to 8 will be mainly described below.

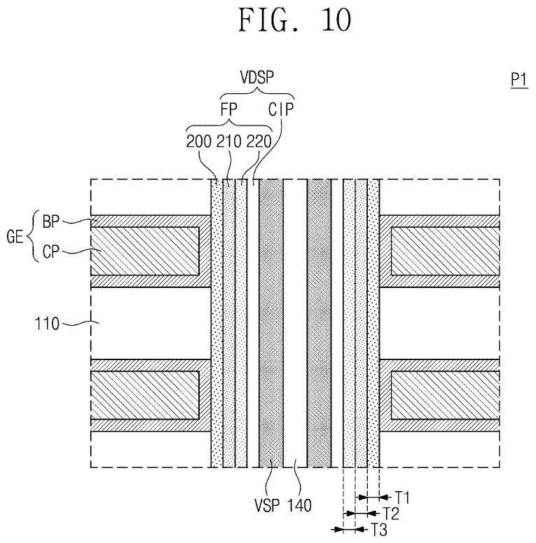

Referring to FIGS. 6, 9, and 10, the vertical data storage pattern VDSP may include the ferroelectric pattern FP, and a channel insulating layer CIP, which is provided between the ferroelectric pattern FP and the vertical semiconductor pattern VSP. In one or more embodiments, the ferroelectric pattern FP and the channel insulating layer CIP may be interposed between each of the gate electrodes GE and the vertical semiconductor pattern VSP and may be extended to a region between each of the insulating layers 110 and the vertical semiconductor pattern VSP. The channel insulating layer CIP may be formed of or include at least one of silicon oxide, silicon oxynitride, high-k dielectric materials having dielectric constants higher than silicon oxide, or combinations thereof. The high-k dielectric materials may include metal oxide materials or metal oxynitride materials. In one or more embodiments, the ferroelectric pattern FP may include the first pattern 200 and the second pattern 210 described with reference to FIG. 7, as shown in FIG. 9. In another embodiment, the ferroelectric pattern FP may include the first pattern 200, the second pattern 210, and the third pattern 220 described with reference to FIG. 8, as shown in FIG. 10.

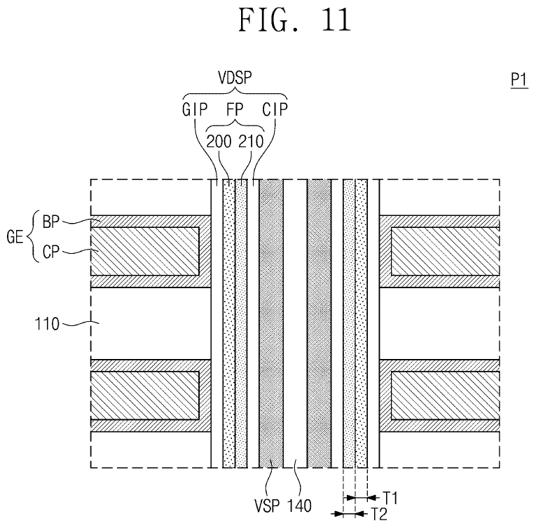

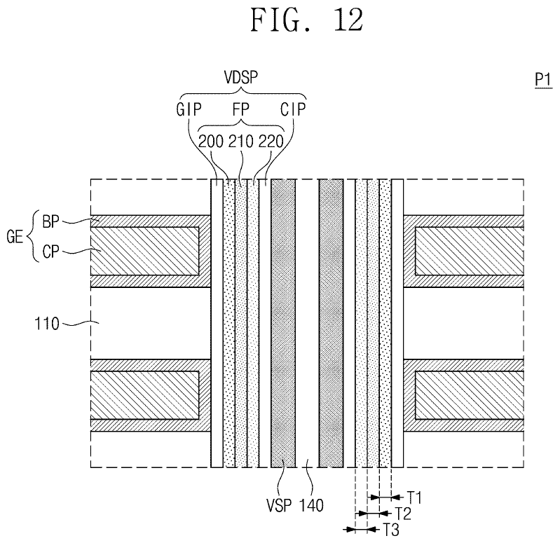

Referring to FIGS. 6, 11, and 12, the vertical data storage pattern VDSP may include the ferroelectric pattern FP, the channel insulating layer CIP between the ferroelectric pattern FP and the vertical semiconductor pattern VSP, and a gate insulating layer GIP between the ferroelectric pattern FP and the stack ST. In one or more embodiments, the ferroelectric pattern FP, the channel insulating layer CIP, and the gate insulating layer GIP may be interposed between each of the gate electrodes GE and the vertical semiconductor pattern VSP and may be extended into a region between each of the insulating layers 110 and the vertical semiconductor pattern VSP. The gate insulating layer GIP may be formed of or include at least one of silicon oxide, silicon oxynitride, high-k dielectric materials having dielectric constants higher than silicon oxide, or combinations thereof. The high-k dielectric materials may include metal oxide materials or metal oxynitride materials. In one or more embodiments, the ferroelectric pattern FP may include the first pattern 200 and the second pattern 210 described with reference to FIG. 7, as shown in FIG. 11. In another embodiment, the ferroelectric pattern FP may include the first pattern 200, the second pattern 210, and the third pattern 220 described with reference to FIG. 8, as shown in FIG. 12.

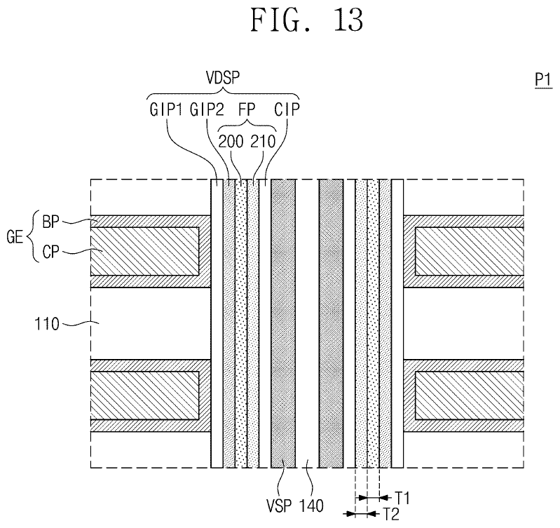

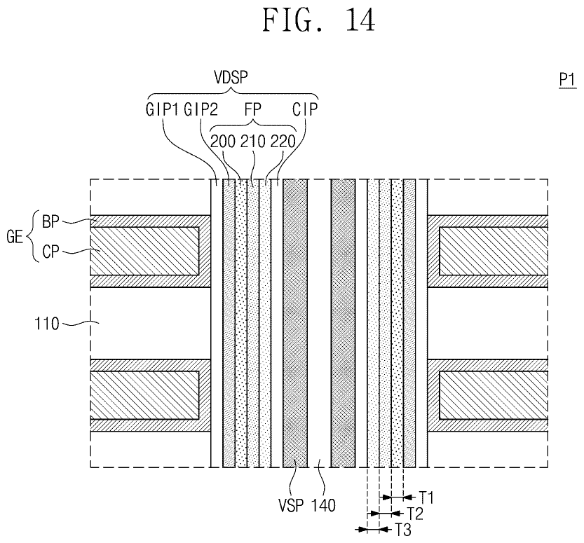

Referring to FIGS. 6, 13, and 14, the vertical data storage pattern VDSP may include the ferroelectric pattern FP, the channel insulating layer CIP between the ferroelectric pattern FP and the vertical semiconductor pattern VSP, a first gate insulating layer GIP1 between the ferroelectric pattern FP and the stack ST, and a second gate insulating layer GIP2 between the ferroelectric pattern FP and the first gate insulating layer GIP1. In one or more embodiments, the ferroelectric pattern FP, the channel insulating layer CIP, and the first and second gate insulating layers GIP1 and GIP2 may be interposed between each of the gate electrodes GE and the vertical semiconductor pattern VSP and may be extended into a region between each of the insulating layers 110 and the vertical semiconductor pattern VSP. The first gate insulating layer GIP1 may be formed of or include at least one of silicon oxide, silicon oxynitride, high-k dielectric materials having dielectric constants higher than silicon oxide, or combinations thereof. The high-k dielectric materials may include metal oxide materials or metal oxynitride materials. The second gate insulating layer GIP2 may be provided to enhance the tunneling of electric charges or holes, and in one or more embodiments, it may include a silicon nitride layer. In one or more embodiments, the ferroelectric pattern FP may include the first pattern 200 and the second pattern 210 described with reference to FIG. 7, as shown in FIG. 13. In another embodiment, the ferroelectric pattern FP may include the first pattern 200, the second pattern 210, and the third pattern 220 described with reference to FIG. 8, as shown in FIG. 14.

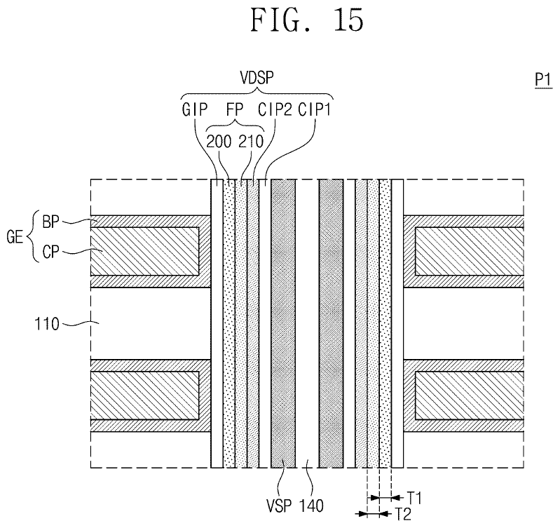

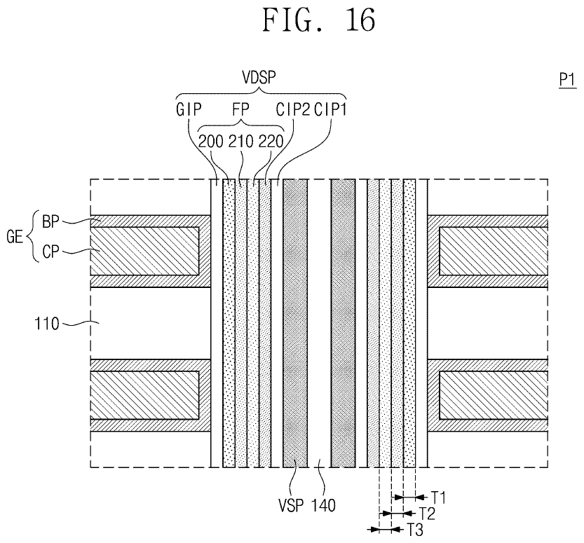

Referring to FIGS. 6, 15, and 16, the vertical data storage pattern VDSP may further include the ferroelectric pattern FP, a first channel insulating layer CIP1 between the ferroelectric pattern FP and the vertical semiconductor pattern VSP, a second channel insulating layer CIP2 between the ferroelectric pattern FP and the first channel insulating layer CIP1, and the gate insulating layer GIP between the ferroelectric pattern FP and the stack ST. In one or more embodiments, the ferroelectric pattern FP, the first and second channel insulating layers CIP1 and CIP2, and the gate insulating layer GIP may be interposed between each of the gate electrodes GE and the vertical semiconductor pattern VSP and may be extended into a region between each of the insulating layers 110 and the vertical semiconductor pattern VSP. The first channel insulating layer CIP1 may be formed of or include at least one of silicon oxide, silicon oxynitride, high-k dielectric materials having dielectric constants higher than silicon oxide, or combinations thereof. The high-k dielectric materials may include metal oxide materials or metal oxynitride materials. The second channel insulating layer CIP2 may be used to adjust a threshold voltage of a ferroelectric field effect transistor including the vertical data storage pattern VDSP and may form an interface dipole. The second channel insulating layer CIP2 may include at least two oxide layers with different oxidation numbers; for example, the second channel insulating layer CIP2 may include two oxide layers, which are respectively formed of two different materials selected from the group consisting of AlOₓ, HfO₂, LaOₓ, and SiO₂. In one or more embodiments, the ferroelectric pattern FP may include the first pattern 200 and the second pattern 210 described with reference to FIG. 7, as shown in FIG. 15. In another embodiment, the ferroelectric pattern FP may include the first pattern 200, the second pattern 210, and the third pattern 220 described with reference to FIG. 8, as shown in FIG. 16.

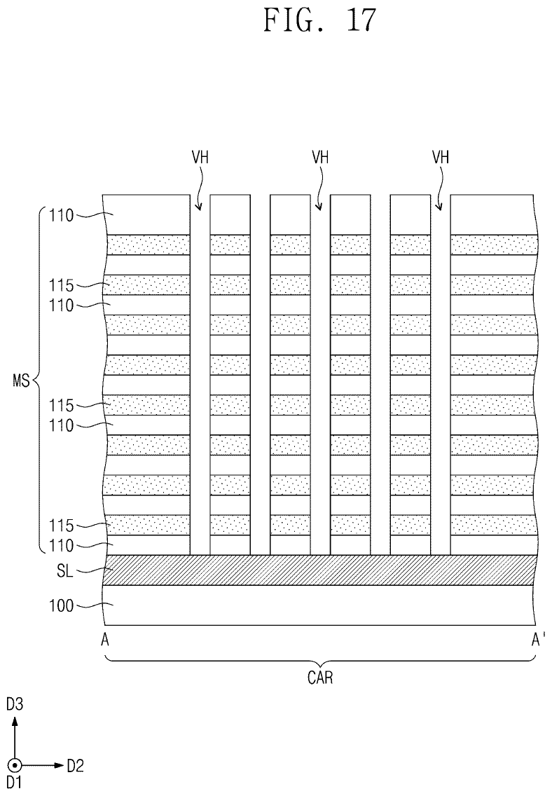

FIGS. 17 to 20 are sectional views corresponding to the line A-A′ of FIG. 5 and illustrating a method of fabricating a three-dimensional semiconductor memory device according to one or more embodiments of the present disclosure. For the sake of brevity, the same element as the three-dimensional semiconductor memory device described with reference to FIGS. 5 to 16 may be identified by the same reference number without repeating an overlapping description.

Referring to FIGS. 5 and 17, a source line SL may be formed on a lower structure 100. The lower structure 100 may include a cell array region CAR and a connection region CNR. The source line SL may be formed on the cell array region CAR of the lower structure 100. The source line SL may be extended to a region on the connection region CNR of the lower structure 100 in the first direction D1, but the present disclosure is not limited to this example. The source line SL may be a plate-shaped structure that is extended in the first and second directions D1 and D2.

A mold structure MS may be formed on the source line SL. The mold structure MS may be disposed on the cell array region CAR of the lower structure 100 and may be extended onto the connection region CNR of the lower structure 100 in the first direction D1. The source line SL may be interposed between the lower structure 100 and the mold structure MS.

The formation of the mold structure MS may include forming a layered structure, in which insulating layers 110 and sacrificial layers 115 are alternately stacked, and repeatedly patterning the layered structure on the connection region CNR. Thus, the mold structure MS may have a stepwise structure on the connection region CNR. The sacrificial layers 115 may be formed of or include a material having an etch selectivity with respect to the insulating layers 110. The sacrificial layers 115 may include an insulating material different from the insulating layers 110. In one or more embodiments, the sacrificial layers 115 may include silicon nitride, and the insulating layers 110 may include silicon oxide.

Vertical holes VH may be formed on the cell array region CAR of the lower structure 100 and in the mold structure MS. Each of the vertical holes VH may be formed to penetrate the mold structure MS and to expose the source line SL. In one or more embodiments, the formation of the vertical holes VH may include performing an anisotropic etching process on the mold structure MS. In one or more examples, dummy vertical holes may be formed on the connection region CNR of the lower structure 100 to penetrate the stepwise structure of the mold structure MS. The dummy vertical holes and the vertical holes VH may be formed at the same time and may be formed using substantially the same method.

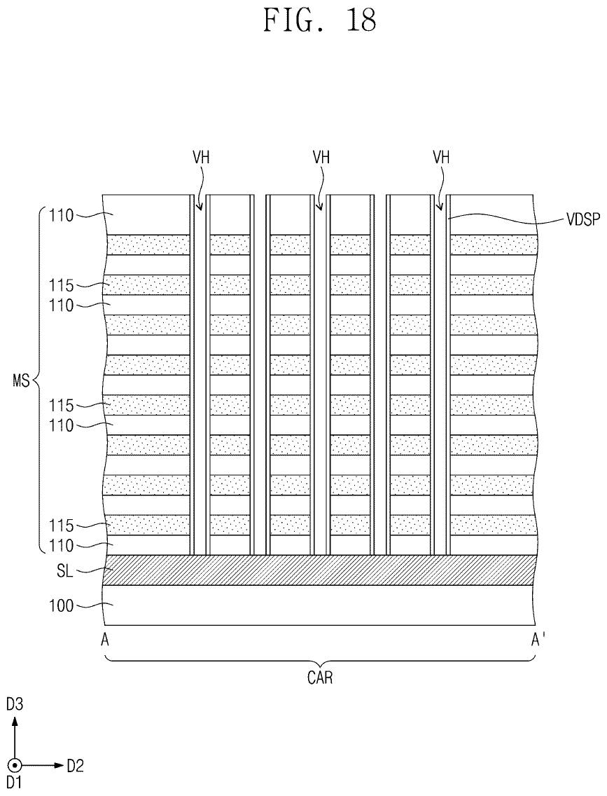

Referring to FIGS. 5 and 18, a vertical data storage pattern VDSP may be formed on an inner side surface of each of the vertical holes VH. The vertical data storage pattern VDSP may be formed to conformally cover the inner side surface of each of the vertical holes VH and to expose the source line SL. The vertical data storage pattern VDSP may have a hollow cylinder shape with an empty region. The formation of the vertical data storage pattern VDSP may include conformally depositing the ferroelectric pattern FP, the channel insulating layer CIP, the gate insulating layer GIP, the first and second gate insulating layers GIP1 and GIP2, and the first and second channel insulating layers CIP1 and CIP2, described with reference to FIGS. 7 to 16, on the inner side surface of each of the vertical holes VH. The deposition process may include, for example, a chemical vapor deposition (CVD) process or an atomic layer deposition (ALD) process.

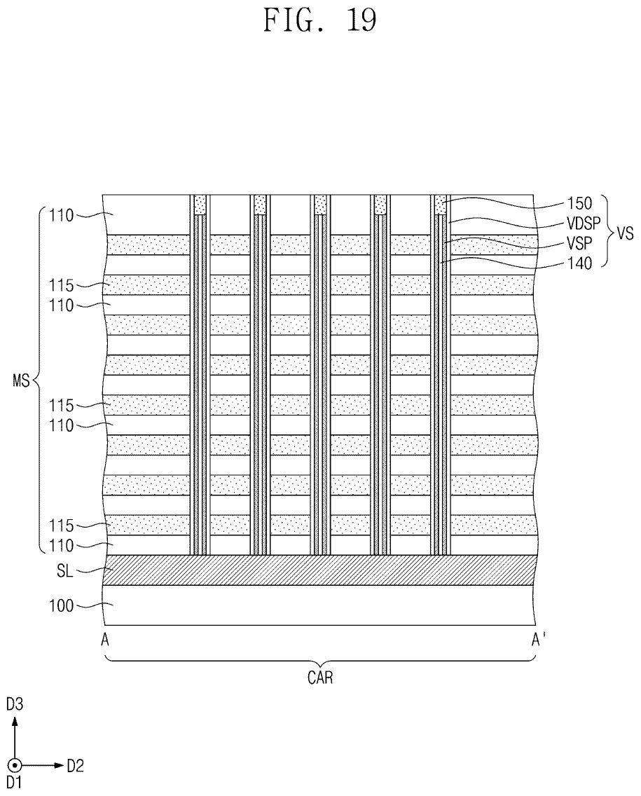

Referring to FIGS. 5 and 19, a vertical semiconductor pattern VSP and a gapfill insulating pattern 140 may be formed to fill each of the vertical holes VH. In one or more embodiments, the formation of the vertical semiconductor pattern VSP and the gapfill insulating pattern 140 may include forming a vertical semiconductor layer on the mold structure MS to fill a portion of each of the vertical holes VH, forming an insulating gapfill layer on the vertical semiconductor layer to fill a remaining portion of each of the vertical holes VH, and planarizing the vertical semiconductor layer and the insulating gapfill layer to expose a top surface of the mold structure MS. A conductive pad 150 may be formed in each of the vertical holes VH. In one or more embodiments, the formation of the conductive pad 150 may include recessing upper portions of the vertical semiconductor pattern VSP and the gapfill insulating pattern 140 to form an empty region in each of the vertical holes VH, forming a conductive layer to fill the empty region, and planarizing the conductive layer to expose a top surface of the mold structure MS.

The vertical data storage pattern VDSP, the vertical semiconductor pattern VSP, the gapfill insulating pattern 140, and the conductive pad 150 may be referred to as a vertical structure VS. In one or more examples, vertical dummy structures DVS may be formed to fill the dummy vertical holes, respectively. The vertical dummy structures DVS may have the same thin film structure as the vertical structures VS and may be formed by substantially the same method as the vertical structures VS. The vertical dummy structures DVS and the vertical structures VS may be formed at the same time (e.g., using the same process).

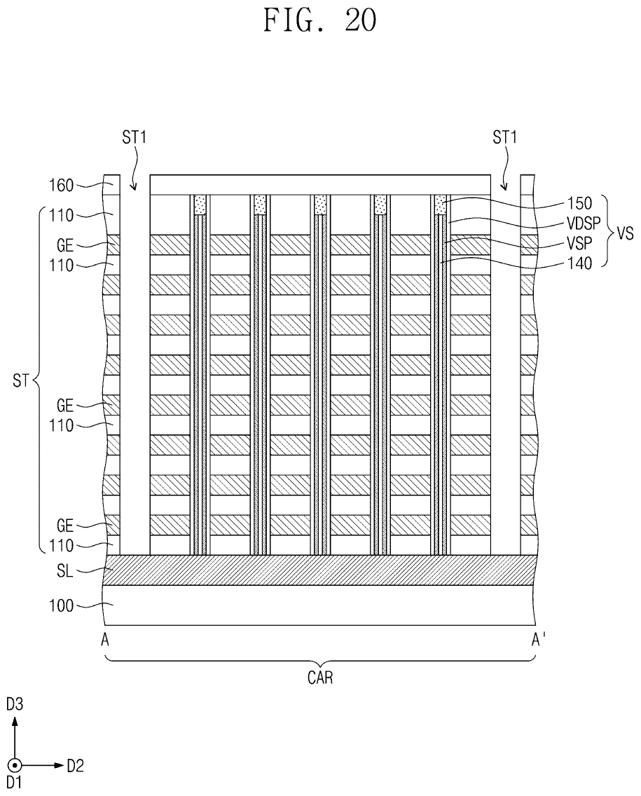

Referring to FIGS. 5 and 20, a planarization insulating layer 160 may be formed on the cell array region CAR and the connection region CNR of the lower structure 100 and on the mold structure MS. The planarization insulating layer 160 may cover top surfaces of the mold structure MS and the vertical structures VS, on the cell array region CAR and may cover the stepwise structure of the mold structure MS, on the connection region CNR.

First separation trenches ST1 may be formed to penetrate the planarization insulating layer 160 and the mold structure MS. The first separation trenches ST1 may be spaced apart from each other in the second direction D2, on the cell array region CAR of the lower structure 100, and may be extended to the connection region CNR of the lower structure 100 in the first direction D1. Each of the first separation trenches ST1 may be extended in the third direction D3 to penetrate the insulating and sacrificial layers 110 and 115 of the mold structure MS. Each of the first separation trenches ST1 may be provided to expose side surfaces of the insulating and sacrificial layers 110 and 115 and a top surface of the source line SL. A second separation trench may be formed on the connection region CNR of the lower structure 100 to penetrate the planarization insulating layer 160 and the mold structure MS. The second separation trench may be extended in the first direction D1, between the first separation trenches ST1. The second separation trench may be extended in the third direction D3 to penetrate the insulating and sacrificial layers 110 and 115 of the mold structure MS and to expose the side surfaces of the insulating and sacrificial layers 110 and 115.

The sacrificial layers 115, which are exposed by the first separation trenches ST1 and the second separation trench, may be removed to form gap regions between the insulating layers 110. Gate electrodes GE may be formed to fill the gap regions. The gate electrodes GE and the insulating layers 110 may be referred to as a stack ST.

Referring back to FIGS. 5 and 6, first separation structures SS1 may be formed in the first separation trenches ST1, respectively, and a second separation structure SS2 may be formed in the second separation trench. The formation of the first and second separation structures SS1 and SS2 may include forming a separation insulating layer to fill the first separation trenches ST1 and the second separation trench and planarizing the separation insulating layer to expose a top surface of the planarization insulating layer 160.

A separation insulating pattern IP may be formed on the cell array region CAR of the lower structure 100 to penetrate an upper portion of the stack ST. The separation insulating pattern IP may be provided to penetrate at least the uppermost one of the insulating layers 110 and the uppermost one of the gate electrodes GE. The separation insulating pattern IP may be extended in the first direction D1, between the first separation structures SS1, and may be extended to the connection region CNR of the lower structure 100 in the first direction D1. The separation insulating pattern IP may be connected to the second separation structure SS2.

An upper insulating layer 170 may be formed on the cell array region CAR and the connection region CNR of the lower structure 100 and on the planarization insulating layer 160. The upper insulating layer 170 may cover top surfaces of the first and second separation structures SS1 and SS2. Bit line contacts 180 may be formed on the cell array region CAR of the lower structure 100. Each of the bit line contacts 180 may be provided to penetrate the upper insulating layer 170 and the planarization insulating layer 160 and may be electrically connected to the conductive pad 150 of each of the vertical structures VS. Cell contact plugs MC may be formed on the connection region CNR of the lower structure 100. The cell contact plugs MC may be provided to penetrate the upper insulating layer 170 and the planarization insulating layer 160 and may be electrically connected to the pad portions GEp of the gate electrodes GE, respectively. Bit lines BL may be formed on the cell array region CAR of the lower structure 100 and on the upper insulating layer 170. Each of the bit lines BL may be electrically connected to the conductive pads 150 and the vertical semiconductor patterns VSP of the vertical structures VS through a corresponding one of the bit line contacts 180.

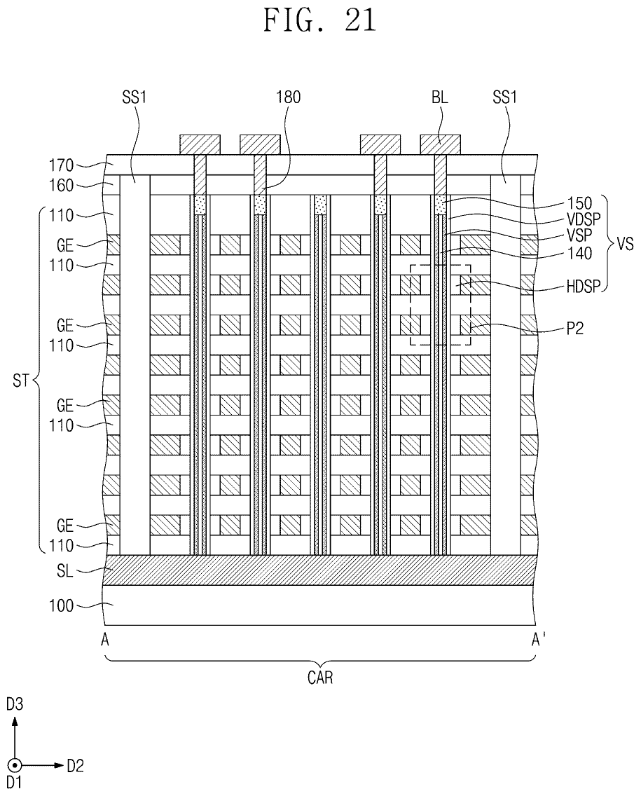

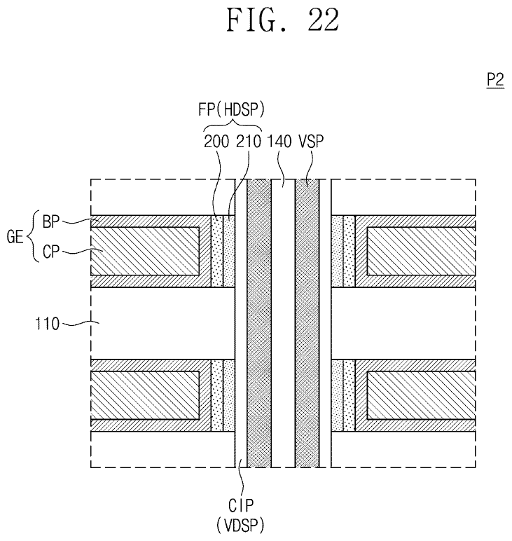

FIG. 21 is a sectional view taken along the line A-A′ of FIG. 5 to illustrate a three-dimensional semiconductor memory device according to one or more embodiments of the present disclosure. FIGS. 22 to 31 are enlarged sectional views illustrating a portion P2 of FIG. 21. For the sake of brevity, features different from the three-dimensional semiconductor memory device described with reference to FIGS. 5 to 16 will be mainly described below.

Referring to FIGS. 5 and 21, vertical structures VS may be disposed on the cell array region CAR of the lower structure 100 to penetrate the stack ST in the third direction D3. The vertical structures VS may be spaced apart from each other in the first and second directions D1 and D2 and may be arranged to form a zigzag shape in the first or second direction D1 or D2. The vertical structures VS may be electrically connected to the source line SL. Each of the vertical structures VS may constitute the memory cell string CSTR of FIG. 1.

Each of the vertical structures VS may include a vertical semiconductor pattern VSP, which is extended in the third direction D3 to penetrate the stack ST, and a vertical data storage pattern VDSP and a horizontal data storage pattern HDSP, which are provided between the vertical semiconductor pattern VSP and the stack ST. In one or more embodiments, the vertical semiconductor pattern VSP may have a hollow cylinder shape with an empty region, and each of the vertical structures VS may further include a gapfill insulating pattern 140 filling the empty region of the vertical semiconductor pattern VSP. The vertical semiconductor pattern VSP and the gapfill insulating pattern 140 may be provided to have substantially the same features as the vertical semiconductor pattern VSP and the gapfill insulating pattern 140 described with reference to FIGS. 5 to 16.

In one or more embodiments, the vertical data storage pattern VDSP may be extended in the third direction D3 to penetrate the stack ST. The vertical data storage pattern VDSP may be extended in the third direction D3 to penetrate the gate electrodes GE and the insulating layers 110 and may be provided to enclose a side surface of the vertical semiconductor pattern VSP. The horizontal data storage pattern HDSP may be interposed between each of the gate electrodes GE and the vertical data storage pattern VDSP and may be interposed between a pair of insulating layers 110, which are closest to each other in the third direction D3. The horizontal data storage pattern HDSP may be a ring-shaped pattern enclosing a side surface of the vertical data storage pattern VDSP. The horizontal data storage pattern HDSP and the vertical data storage pattern VDSP may be referred to as a data storage pattern.

Each of the vertical structures VS may further include a conductive pad 150 connected to an upper portion of the vertical semiconductor pattern VSP. The conductive pad 150 may be disposed on the vertical semiconductor pattern VSP and the gapfill insulating pattern 140. The vertical data storage pattern VDSP may be extended to a side surface of the conductive pad 150 to enclose the side surface of the conductive pad 150, but the present disclosure is not limited to this example. The conductive pad 150 may be provided to have substantially the same features as the conductive pad 150 described with reference to FIGS. 5 to 16.

Referring to FIGS. 21, 22, and 23, the horizontal data storage pattern HDSP may include a ferroelectric pattern FP, and the vertical data storage pattern VDSP may include a channel insulating layer CIP. In one or more embodiments, the channel insulating layer CIP may be interposed between each of the gate electrodes GE and the vertical semiconductor pattern VSP and may be extended into a region between each of the insulating layers 110 and the vertical semiconductor pattern VSP. The channel insulating layer CIP may be formed of or include at least one of silicon oxide, silicon oxynitride, high-k dielectric materials having dielectric constants higher than silicon oxide, or combinations thereof. The high-k dielectric materials may include metal oxide materials or metal oxynitride materials.

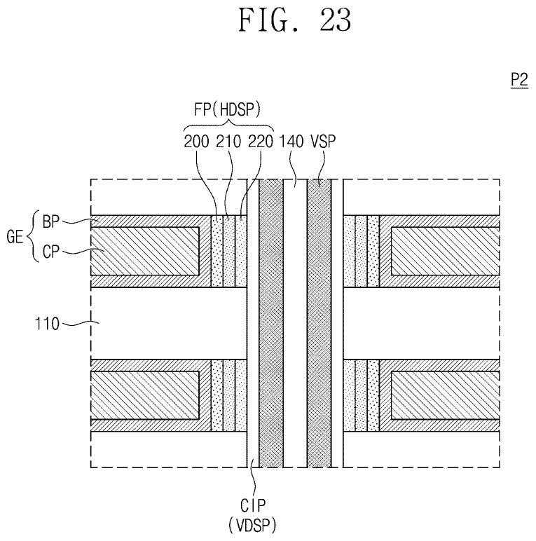

The ferroelectric pattern FP may be interposed between each of the gate electrodes GE and the channel insulating layer CIP and may be interposed between a pair of insulating layers 110, which are closest to each other in the third direction D3. The ferroelectric pattern FP may be provided to have substantially the same features as the ferroelectric pattern FP described with reference to FIGS. 5 to 16. In one or more embodiments, the ferroelectric pattern FP may include a first pattern 200 between each of the gate electrodes GE and the channel insulating layer CIP and a second pattern 210 between the first pattern 200 and the channel insulating layer CIP, as shown in FIG. 22. The first pattern 200 and the second pattern 210 may be provided to have substantially the same features as the first pattern 200 and the second pattern 210 described with reference to FIG. 7. In another embodiment, the ferroelectric pattern FP may include a first pattern 200 between each of the gate electrodes GE and the channel insulating layer CIP, a second pattern 210 between the first pattern 200 and the channel insulating layer CIP, and a third pattern 220 between the second pattern 210 and the channel insulating layer CIP, as shown in FIG. 23. The first pattern 200, the second pattern 210, and the third pattern 220 may be provided to have substantially the same features as the first pattern 200, the second pattern 210, and the third pattern 220 described with reference to FIG. 8.

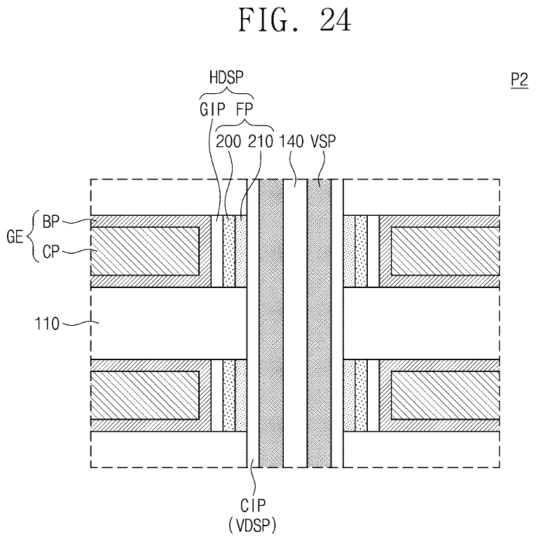

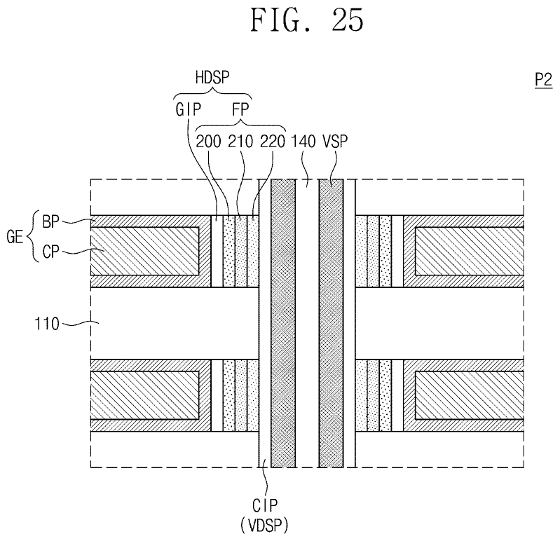

Referring to FIGS. 21, 24, and 25, the horizontal data storage pattern HDSP may include the ferroelectric pattern FP and a gate insulating layer GIP, which is placed between each of the gate electrodes GE and the ferroelectric pattern FP, and the vertical data storage pattern VDSP may include the channel insulating layer CIP. In one or more embodiments, the ferroelectric pattern FP and the gate insulating layer GIP may be interposed between each of the gate electrodes GE and the channel insulating layer CIP and may be interposed between a pair of insulating layers 110, which are closest to each other in the third direction D3. The gate insulating layer GIP may be formed of or include at least one of silicon oxide, silicon oxynitride, high-k dielectric materials having dielectric constants higher than silicon oxide, or combinations thereof. The high-k dielectric materials may include metal oxide materials or metal oxynitride materials. In one or more embodiments, the ferroelectric pattern FP may include a first pattern 200 between the gate insulating layer GIP and the channel insulating layer CIP and a second pattern 210 between the first pattern 200 and the channel insulating layer CIP, as shown in FIG. 24. The first pattern 200 and the second pattern 210 may be provided to have substantially the same features as the first pattern 200 and the second pattern 210 described with reference to FIG. 7. In another embodiment, the ferroelectric pattern FP may include a first pattern 200 between the gate insulating layer GIP and the channel insulating layer CIP, a second pattern 210 between the first pattern 200 and the channel insulating layer CIP, and a third pattern 220 between the second pattern 210 and the channel insulating layer CIP, as shown in FIG. 25. The first pattern 200, the second pattern 210, and the third pattern 220 may be provided to have substantially the same features as the first pattern 200, the second pattern 210, and the third pattern 220 described with reference to FIG. 8.

Referring to FIGS. 21, 26, and 27, the horizontal data storage pattern HDSP may include the ferroelectric pattern FP, a first gate insulating layer GIP1, which is placed between each of the gate electrodes GE and the ferroelectric pattern FP, and a second gate insulating layer GIP2, which is placed between the first gate insulating layer GIP1 and the ferroelectric pattern FP, and the vertical data storage pattern VDSP may include the channel insulating layer CIP. In one or more embodiments, the ferroelectric pattern FP and the first and second gate insulating layers GIP1 and GIP2 may be interposed between each of the gate electrodes GE and the channel insulating layer CIP and may be interposed between a pair of insulating layers 110, which are closest to each other in the third direction D3. The first gate insulating layer GIP1 may be formed of or include at least one of silicon oxide, silicon oxynitride, high-k dielectric materials having dielectric constants higher than silicon oxide, or combinations thereof. The high-k dielectric materials may include metal oxide materials or metal oxynitride materials. The second gate insulating layer GIP2 may be provided to enhance the tunneling of electric charges or holes, and in one or more embodiments, it may include a silicon nitride layer.

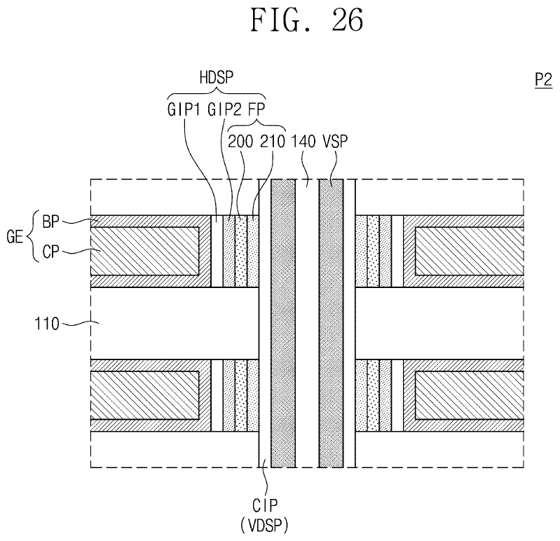

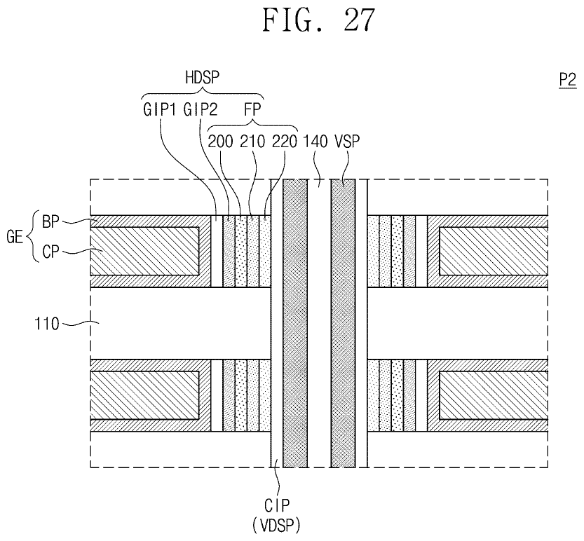

In one or more embodiments, the ferroelectric pattern FP may include a first pattern 200 between the second gate insulating layer GIP2 and the channel insulating layer CIP and a second pattern 210 between the first pattern 200 and the channel insulating layer CIP, as shown in FIG. 26. The first pattern 200 and the second pattern 210 may be provided to have substantially the same features as the first pattern 200 and the second pattern 210 described with reference to FIG. 7. In another embodiment, the ferroelectric pattern FP may include a first pattern 200 between the second gate insulating layer GIP2 and the channel insulating layer CIP, a second pattern 210 between the first pattern 200 and the channel insulating layer CIP, and a third pattern 220 between the second pattern 210 and the channel insulating layer CIP, as shown in FIG. 27. The first pattern 200, the second pattern 210, and the third pattern 220 may be provided to have substantially the same features as the first pattern 200, the second pattern 210, and the third pattern 220 described with reference to FIG. 8.

Referring to FIGS. 21, 28, and 29, the vertical data storage pattern VDSP may include a first channel insulating layer CIP1, and the horizontal data storage pattern HDSP may include the ferroelectric pattern FP, a gate insulating layer GIP between each of the gate electrodes GE and the ferroelectric pattern FP, and a second channel insulating layer CIP2 between the ferroelectric pattern FP and the first channel insulating layer CIP1. In one or more embodiments, the first channel insulating layer CIP1 may be interposed between each of the gate electrodes GE and the vertical semiconductor pattern VSP and may be extended into a region between each of the insulating layers 110 and the vertical semiconductor pattern VSP. The ferroelectric pattern FP, the gate insulating layer GIP, and the second channel insulating layer CIP2 may be interposed between each of the gate electrodes GE and the first channel insulating layer CIP1 and may be interposed between a pair of insulating layers 110, which are closest to each other in the third direction D3.

The first channel insulating layer CIP1 may be formed of or include at least one of silicon oxide, silicon oxynitride, high-k dielectric materials having dielectric constants higher than silicon oxide, or combinations thereof. The high-k dielectric materials may include metal oxide materials or metal oxynitride materials. The second channel insulating layer CIP2 may be used to adjust a threshold voltage of a ferroelectric field effect transistor including the vertical and horizontal data storage patterns VDSP and HDSP and may form an interface dipole. The second channel insulating layer CIP2 may include at least two oxide layers with different oxidation numbers; for example, the second channel insulating layer CIP2 may include two oxide layers, which are respectively formed of two different materials selected from the group consisting of AlOₓ, HfO₂, LaOₓ, and SiO₂.

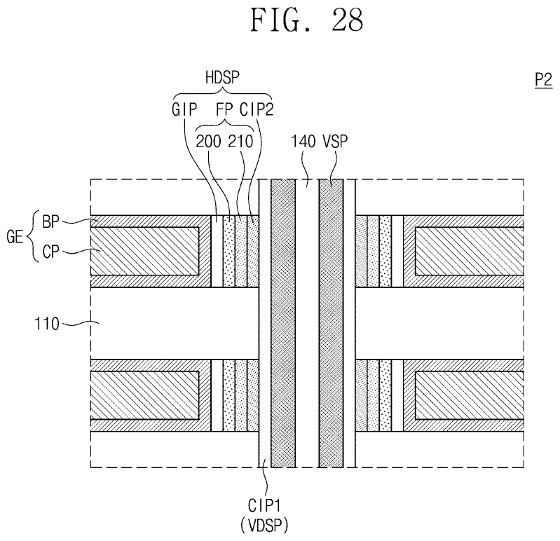

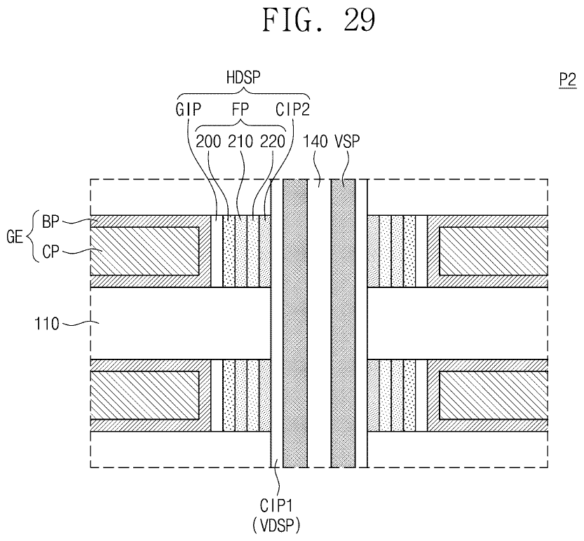

In one or more embodiments, the ferroelectric pattern FP may include a first pattern 200 between the gate insulating layer GIP and the second channel insulating layer CIP2 and a second pattern 210 between the first pattern 200 and the second channel insulating layer CIP2, as shown in FIG. 28. The first pattern 200 and the second pattern 210 may be provided to have substantially the same features as the first pattern 200 and the second pattern 210 described with reference to FIG. 7. In another embodiment, the ferroelectric pattern FP may include a first pattern 200 between the gate insulating layer GIP and the second channel insulating layer CIP2, a second pattern 210 between the first pattern 200 and the second channel insulating layer CIP2, and a third pattern 220 between the second pattern 210 and the second channel insulating layer CIP2, as shown in FIG. 29. The first pattern 200, the second pattern 210, and the third pattern 220 may be provided to have substantially the same features as the first pattern 200, the second pattern 210, and the third pattern 220 described with reference to FIG. 8.

Referring to FIGS. 21, 30, and 31, the vertical data storage pattern VDSP may include the first channel insulating layer CIP1, and the second channel insulating layer CIP2, which is placed between the first channel insulating layer CIP1 and the stack ST. The horizontal data storage pattern HDSP may include the ferroelectric pattern FP and the gate insulating layer GIP, which is placed between each of the gate electrodes GE and the ferroelectric pattern FP. In one or more embodiments, the first and second channel insulating layers CIP1 and CIP2 may be interposed between each of the gate electrodes GE and the vertical semiconductor pattern VSP and may be extended into a region between each of the insulating layers 110 and the vertical semiconductor pattern VSP. The ferroelectric pattern FP and the gate insulating layer GIP may be interposed between each of the gate electrodes GE and the second channel insulating layer CIP2 and may be interposed between a pair of insulating layers 110, which are closest to each other in the third direction D3.

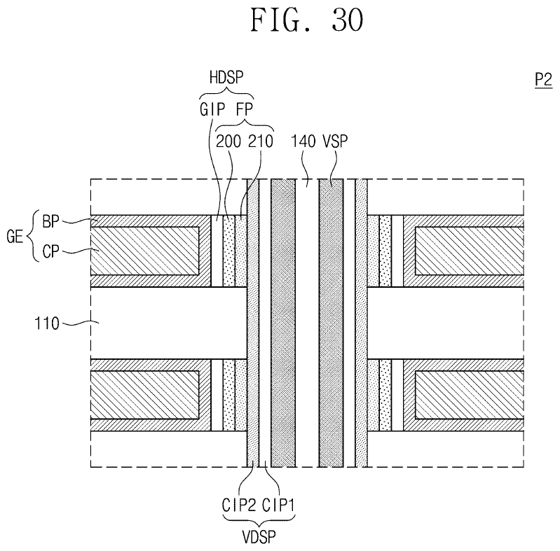

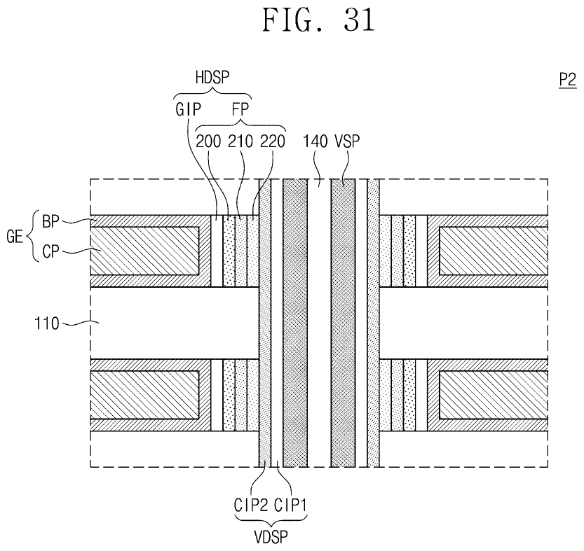

In one or more embodiments, the ferroelectric pattern FP may include a first pattern 200 between the gate insulating layer GIP and the second channel insulating layer CIP2 and a second pattern 210 between the first pattern 200 and the second channel insulating layer CIP2, as shown in FIG. 30. The first pattern 200 and the second pattern 210 may be provided to have substantially the same features as the first pattern 200 and the second pattern 210 described with reference to FIG. 7. In another embodiment, the ferroelectric pattern FP may include a first pattern 200 between the gate insulating layer GIP and the second channel insulating layer CIP2, a second pattern 210 between the first pattern 200 and the second channel insulating layer CIP2, and a third pattern 220 between the second pattern 210 and the second channel insulating layer CIP2, as shown in FIG. 31. The first pattern 200, the second pattern 210, and the third pattern 220 may be provided to have substantially the same features as the first pattern 200, the second pattern 210, and the third pattern 220 described with reference to FIG. 8.

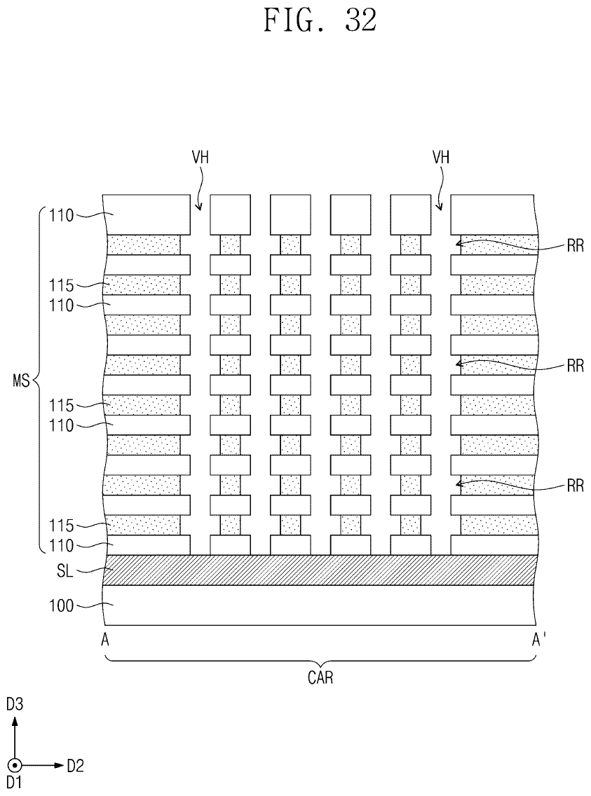

FIGS. 32 to 34 are sectional views corresponding to the line A-A′ of FIG. 5 and illustrating a method of fabricating a three-dimensional semiconductor memory device according to one or more embodiments of the present disclosure. For the sake of brevity, features different from the fabrication method described with reference to FIGS. 17 to 20 will be mainly described below.

First, as described with reference to FIGS. 5 and 17, the source line SL may be formed on the lower structure 100, and the mold structure MS may be formed on the source line SL. The vertical holes VH may be formed on the cell array region CAR of the lower structure 100 and in the mold structure MS. Each of the vertical holes VH may be formed to penetrate the mold structure MS and to expose the source line SL.

Referring to FIGS. 5 and 32, each of the vertical holes VH may be formed to expose side surfaces of the sacrificial layers 115. The exposed side surfaces of the sacrificial layers 115 may be recessed to form recess regions RR between the insulating layers 110. In one or more embodiments, the formation of the recess regions RR may include partially removing the exposed side surfaces of the sacrificial layers 115 through a wet etching process.

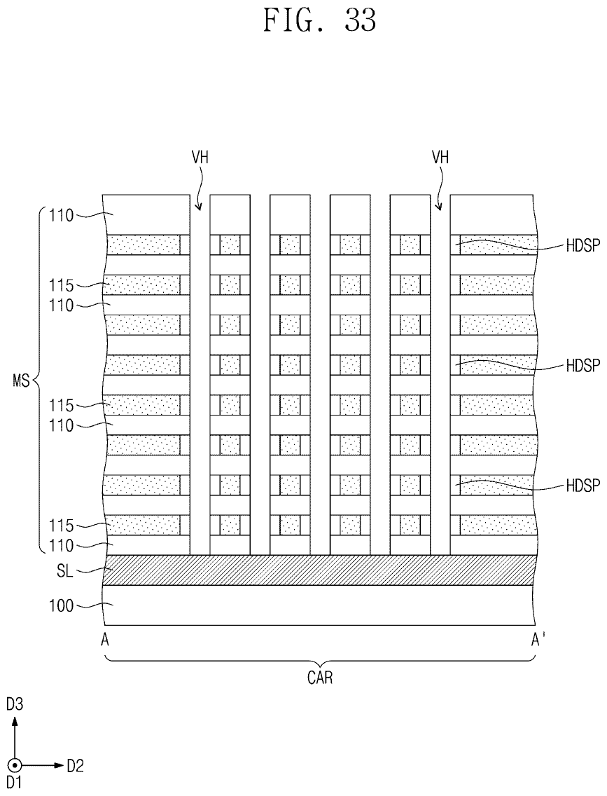

Referring to FIGS. 5 and 33, a horizontal data storage pattern HDSP may be formed to fill each of the recess regions RR. The formation of the horizontal data storage pattern HDSP may include selectively depositing the ferroelectric pattern FP, the gate insulating layer GIP, the first and second gate insulating layers GIP1 and GIP2, and the second channel insulating layer CIP2, described with reference to FIGS. 22 to 31, on side surfaces of the sacrificial layers 115. The deposition process may include, for example, an area-selective atomic layer deposition process (ASD).

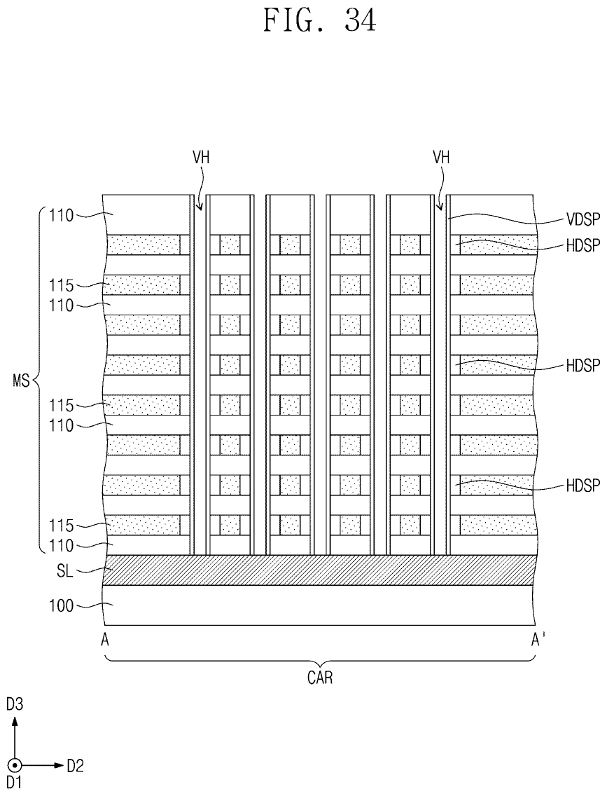

Referring to FIGS. 5 and 34, a vertical data storage pattern VDSP may be formed on an inner side surface of each of the vertical holes VH. The vertical data storage pattern VDSP may be formed to conformally cover the inner side surface of each of the vertical holes VH and to expose the source line SL. The vertical data storage pattern VDSP may have a hollow cylinder shape with an empty region. The formation of the vertical data storage pattern VDSP may include conformally depositing the first and second channel insulating layers CIP1 and CIP2 described with reference to FIGS. 22 to 31, on the inner side surface of each of the vertical holes VH. The deposition process may include, for example, a chemical vapor deposition (CVD) process or an atomic layer deposition (ALD) process.

A subsequent process may be performed using substantially the same method as described with reference to FIGS. 17 to 20.

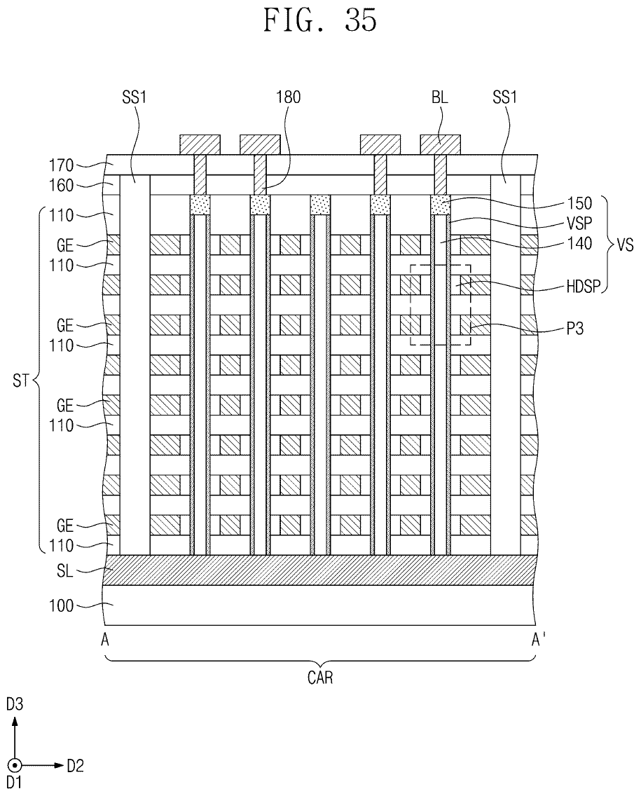

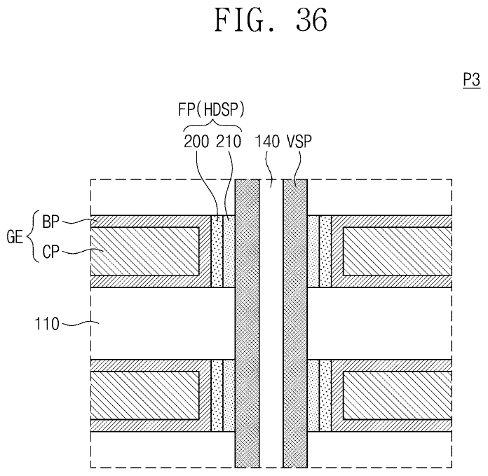

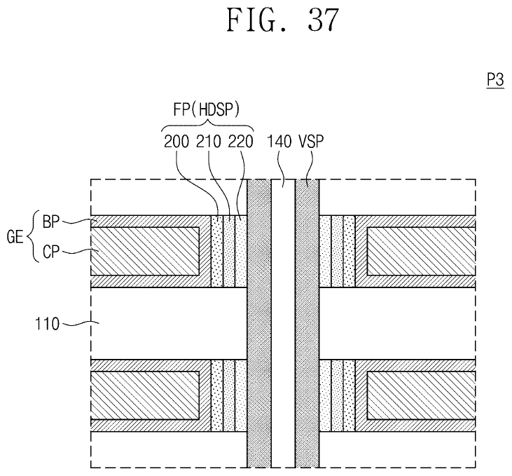

FIG. 35 is a sectional view, which is taken along the line A-A′ of FIG. 5 to illustrate a three-dimensional semiconductor memory device according to one or more embodiments of the present disclosure. FIGS. 36 and 37 are enlarged sectional views illustrating a portion P3 of FIG. 35. For the sake of brevity, features different from the three-dimensional semiconductor memory device described with reference to FIGS. 5 to 16 will be mainly described below.

Referring to FIGS. 5 and 35, vertical structures VS may be disposed on the cell array region CAR of the lower structure 100 to penetrate the stack ST in the third direction D3. The vertical structures VS may be spaced apart from each other in the first and second directions D1 and D2 and may be arranged to form a zigzag shape in the first or second direction D1 or D2. The vertical structures VS may be electrically connected to the source line SL. Each of the vertical structures VS may constitute the memory cell string CSTR of FIG. 1.

Each of the vertical structures VS may include a vertical semiconductor pattern VSP, which is extended in the third direction D3 to penetrate the stack ST, and a horizontal data storage pattern HDSP, which is provided between the vertical semiconductor pattern VSP and the stack ST. In one or more embodiments, the vertical semiconductor pattern VSP may have a hollow cylinder shape with an empty region, and each of the vertical structures VS may further include a gapfill insulating pattern 140 filling the empty region of the vertical semiconductor pattern VSP. The vertical semiconductor pattern VSP and the gapfill insulating pattern 140 may be provided to have substantially the same features as the vertical semiconductor pattern VSP and the gapfill insulating pattern 140 described with reference to FIGS. 5 to 16.

In one or more embodiments, the horizontal data storage pattern HDSP may be interposed between each of the gate electrodes GE and the vertical semiconductor pattern VSP and may be interposed between a pair of insulating layers 110, which are closest to each other in the third direction D3. The horizontal data storage pattern HDSP may be a ring-shaped pattern enclosing a side surface of the vertical semiconductor pattern VSP. The horizontal data storage pattern HDSP may be referred to as a data storage pattern.

Each of the vertical structures VS may further include a conductive pad 150 connected to an upper portion of the vertical semiconductor pattern VSP. The conductive pad 150 may be disposed on the vertical semiconductor pattern VSP and the gapfill insulating pattern 140. The conductive pad 150 may be provided to have substantially the same features as the conductive pad 150 described with reference to FIGS. 5 to 16.

Referring to FIGS. 35, 36, and 37, the horizontal data storage pattern HDSP may include a ferroelectric pattern FP. The ferroelectric pattern FP may be interposed between each of the gate electrodes GE and the vertical semiconductor pattern VSP and may be interposed between a pair of insulating layers 110, which are closest to each other in the third direction D3. The ferroelectric pattern FP may be provided to have substantially the same features as the ferroelectric pattern FP described with reference to FIGS. 5 to 16. In one or more embodiments, the ferroelectric pattern FP may include a first pattern 200 between each of the gate electrodes GE and the vertical semiconductor pattern VSP and a second pattern 210 between the first pattern 200 and the vertical semiconductor pattern VSP, as shown in FIG. 36. The first pattern 200 and the second pattern 210 may be provided to have substantially the same features as the first pattern 200 and the second pattern 210 described with reference to FIG. 7. In another embodiment, the ferroelectric pattern FP may include a first pattern 200 between each of the gate electrodes GE and the vertical semiconductor pattern VSP, a second pattern 210 between the first pattern 200 and the vertical semiconductor pattern VSP, and a third pattern 220 between the second pattern 210 and the vertical semiconductor pattern VSP, as shown in FIG. 37. The first pattern 200, the second pattern 210, and the third pattern 220 may be provided to have substantially the same features as the first pattern 200, the second pattern 210, and the third pattern 220 described with reference to FIG. 8.

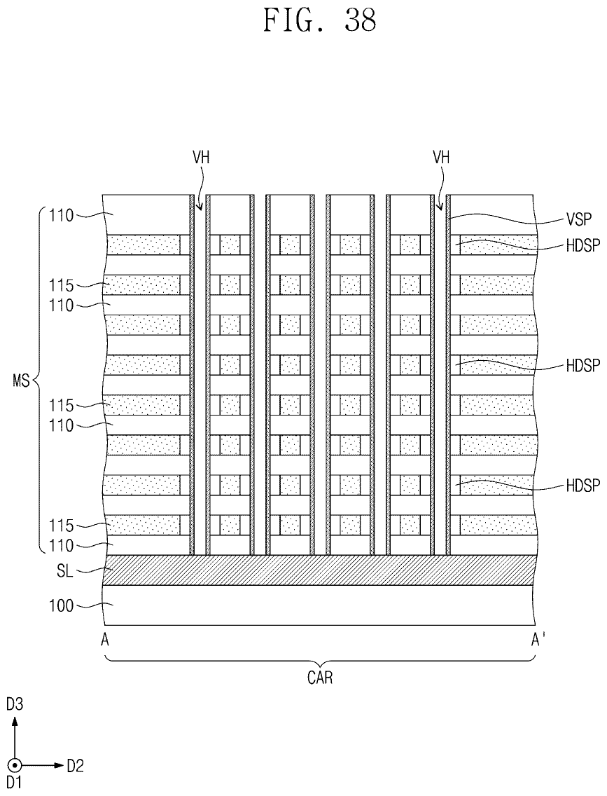

FIG. 38 is a sectional view corresponding the line A-A′ of FIG. 5 and illustrating a method of fabricating a three-dimensional semiconductor memory device, according to one or more embodiments of the present disclosure. For the sake of brevity, features different from the fabrication method described with reference to FIGS. 17 to 20 will be mainly described below.

First, as described with reference to FIGS. 5 and 17, the source line SL may be formed on the lower structure 100, and the mold structure MS may be formed on the source line SL. The vertical holes VH may be formed on the cell array region CAR of the lower structure 100 and in the mold structure MS. Each of the vertical holes VH may be formed to penetrate the mold structure MS and to expose the source line SL.

Each of the vertical holes VH may expose side surfaces of the sacrificial layers 115, as described with reference to FIGS. 5 and 32. The exposed side surfaces of the sacrificial layers 115 may be recessed to form recess regions RR between the insulating layers 110.

Referring to FIGS. 5 and 38, a horizontal data storage pattern HDSP may be formed to fill each of the recess regions RR. The formation of the horizontal data storage pattern HDSP may include selectively depositing the ferroelectric pattern FP described with reference to FIGS. 36 and 37 on side surfaces of the sacrificial layers 115. The deposition process may include, for example, an area-selective atomic layer deposition process (ASD). A vertical semiconductor pattern VSP may be formed on an inner side surface of each of the vertical holes VH. The vertical semiconductor pattern VSP may be formed to conformally cover the inner side surface of each of the vertical holes VH and to expose the source line SL. The vertical semiconductor pattern VSP may have a hollow cylinder shape with an empty region.

A subsequent process may be performed using substantially the same method as described with reference to FIGS. 17 to 20.

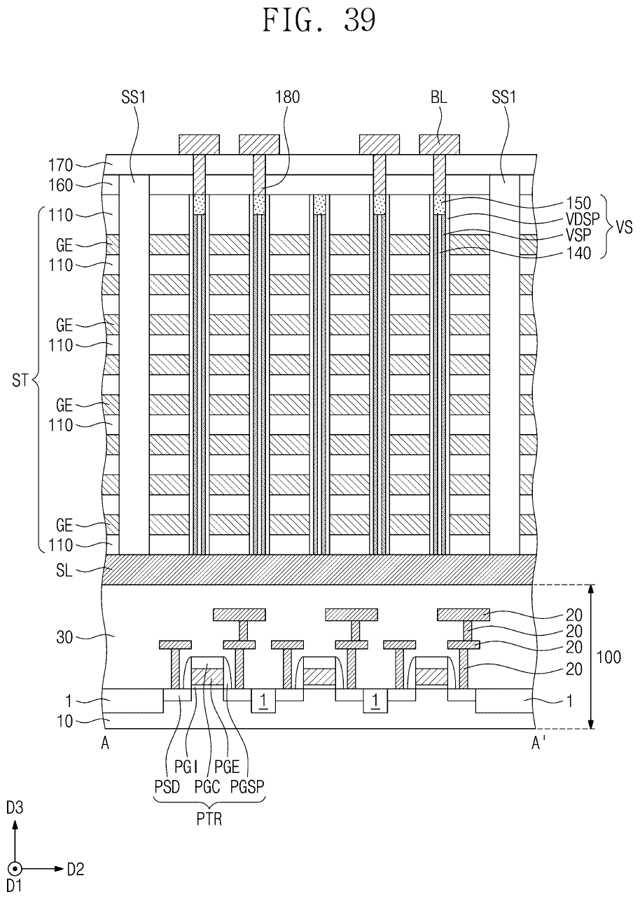

FIG. 39 is a sectional view taken along the line A-A′ of FIG. 5 to illustrate a three-dimensional semiconductor memory device according to one or more embodiments of the present disclosure. For the sake of brevity, features different from the three-dimensional semiconductor memory device described with reference to FIGS. 5 to 16 will be mainly described below.

Referring to FIGS. 5 and 39, the lower structure 100 may include a semiconductor substrate 10, peripheral transistors PTR on the semiconductor substrate 10, peripheral interconnection patterns 20 electrically connected to the peripheral transistors PTR, and a lower insulating layer 30 disposed on the semiconductor substrate 10 to cover the peripheral transistors PTR and the peripheral interconnection patterns 20. The peripheral transistors PTR and the peripheral interconnection patterns 20 may correspond to the first structure 1100F of FIG. 1.

In one or more embodiments, the semiconductor substrate 10 may include a silicon substrate, a silicon-germanium substrate, a germanium substrate, or a single-crystalline epitaxial layer grown from a single-crystalline silicon substrate. A device isolation layer 1 may be disposed in the semiconductor substrate 10 to define an active region. The device isolation layer 1 may be formed of or include an insulating material (e.g., silicon oxide, silicon nitride, and/or silicon oxynitride).

The peripheral transistors PTR may be disposed on the active region of the semiconductor substrate 10 to constitute row and column decoders, a page buffer, and a control circuit. Each of the peripheral transistors PTR may include a peripheral gate electrode PGE on the semiconductor substrate 10, a peripheral gate insulating layer PGI between the semiconductor substrate 10 and the peripheral gate electrode PGE, a peripheral gate capping pattern PGC on the peripheral gate electrode PGE, peripheral gate spacers PGSP on opposite side surfaces of the peripheral gate electrode PGE, and peripheral source/drain regions PSD disposed in portions of the semiconductor substrate 10 at both sides of the peripheral gate electrode PGE. The peripheral gate electrode PGE may include a conductive material (e.g., doped semiconductor materials or metallic materials), and the peripheral gate insulating layer PGI, the peripheral gate capping pattern PGC, and the peripheral gate spacers PGSP may include at least one of silicon oxide, silicon oxynitride, or silicon nitride. The peripheral source/drain regions PSD may be regions, which are formed by injecting n-or p-type impurities into the semiconductor substrate 10.

The peripheral interconnection patterns 20 may be electrically connected to gate or source/drain terminals of the peripheral transistors PTR. For example, the peripheral interconnection patterns 20 may be electrically connected to the peripheral gate electrode PGE or the peripheral source/drain regions PSD. The peripheral interconnection patterns 20 may include a conductive material (e.g., doped semiconductor materials or metallic materials).

The lower insulating layer 30 may include a silicon oxide layer, a silicon nitride layer, a silicon oxynitride layer, and/or a low-k dielectric layer.

Except for the afore-described differences, the three-dimensional semiconductor memory device according to the present embodiments may be configured to have substantially the same features as one of the three-dimensional semiconductor memory devices described with reference to FIGS. 5 to 16, FIGS. 21 to 31, and FIGS. 35 to 37.

According to one or more embodiments of the present disclosure, a three-dimensional semiconductor memory device may include gate electrodes, which are stacked in a vertical direction, a vertical semiconductor pattern, which is extended in the vertical direction to penetrate the gate electrodes, and a data storage pattern, which is interposed between the gate electrodes and the vertical semiconductor pattern, and the data storage pattern may include a ferroelectric pattern. The gate electrodes, the vertical semiconductor pattern, and the data storage pattern may constitute ferroelectric field effect transistors. The ferroelectric pattern may have an effective dielectric constant ranging from 1 to 15. Accordingly, a capacitance between the gate electrodes and the vertical semiconductor pattern may be reduced, and thus, it may be possible to improve operational characteristics of reading and writing operations on memory cells composed of the ferroelectric field effect transistors. In addition, the ferroelectric field effect transistors may be stacked in a vertical direction, and thus, it may be possible to easily increase an integration density of the ferroelectric field effect transistors in the semiconductor memory device.

As a result, it may be possible to improve electrical and operational characteristics of ferroelectric field effect transistors and to easily increase an integration density of a three-dimensional semiconductor memory device with the ferroelectric field effect transistors.

While example embodiments of the present disclosure have been particularly shown and described, it will be understood by one of ordinary skill in the art that variations in form and detail may be made therein without departing from the spirit and scope of the attached claims.

What is claimed is:

1. A three-dimensional semiconductor memory device, comprising:
a stack on a first structure, the stack comprising gate electrodes and insulating layers, which are alternately stacked in a first direction perpendicular to a top surface of the first structure; and
a second structure extended in the first direction to penetrate the stack,
wherein the second structure comprises:
a semiconductor pattern extended in the first direction to penetrate the stack; and
a data storage pattern between the stack and the semiconductor pattern,
wherein the data storage pattern comprises a ferroelectric pattern,
wherein the ferroelectric pattern comprises a first pattern and a second pattern in which the first pattern has a first dielectric constant and the second pattern has a second dielectric constant different from the first dielectric constant, and
wherein an effective dielectric constant of the ferroelectric pattern ranges from 1 to 15.

2. The 3D semiconductor memory device of claim 1, wherein the second dielectric constant of the second pattern is lower than the first dielectric constant of the first pattern, and
the second pattern comprises a material having a higher crystallization temperature than the first pattern.

3. The 3D semiconductor memory device of claim 2, wherein the second pattern has an amorphous structure.

4. The 3D semiconductor memory device of claim 2, wherein the second pattern comprises a material having a band gap energy greater than the first pattern.

5. The 3D semiconductor memory device of claim 1, wherein the ferroelectric pattern further comprises a third pattern,
the second pattern is between the first pattern and the third pattern, and
the second dielectric constant of the second pattern is lower than the first dielectric constant of the first pattern, and
the second dielectric constant is lower than a third dielectric constant of the third pattern.

6. The 3D semiconductor memory device of claim 5, wherein the second pattern comprises a material having a higher crystallization temperature than the first pattern and the third pattern.

7. The 3D semiconductor memory device of claim 6, wherein the second pattern has an amorphous structure.

8. The 3D semiconductor memory device of claim 5, wherein the second pattern comprises a material having a band gap energy greater than the first and third patterns.

9. The 3D semiconductor memory device of claim 1, wherein the data storage pattern further comprises a channel insulating layer between the ferroelectric pattern and the semiconductor pattern.

10. The 3D semiconductor memory device of claim 9, wherein the data storage pattern further comprises a gate insulating layer between the stack and the ferroelectric pattern.

11. The 3D semiconductor memory device of claim 1, wherein the ferroelectric pattern is between each of the gate electrodes and the semiconductor pattern and between the insulating layers.

12. A three-dimensional (3D) semiconductor memory device, comprising:
a stack on a first structure, the stack comprising gate electrodes and insulating layers, which are alternately stacked in a first direction perpendicular to a top surface of the first structure;
a semiconductor pattern extended in the first direction to penetrate the stack; and
a data storage pattern between the stack and the semiconductor pattern,
wherein the data storage pattern comprises a ferroelectric pattern, and
wherein an effective dielectric constant of the ferroelectric pattern ranges from 1 to 15.

13. The 3D semiconductor memory device of claim 12, wherein the ferroelectric pattern comprises at least one of doped aluminum nitride, doped zinc oxide, two-dimensional ferroelectric materials, or a laminated structure, in which ferroelectric layers and low-k dielectric layers are stacked.

14. The 3D semiconductor memory device of claim 12, wherein the ferroelectric pattern comprises a first pattern between the stack and the semiconductor pattern and a second pattern between the first pattern and the semiconductor pattern, and
wherein the first pattern has a first dielectric constant and the second pattern has a second dielectric constant different from the first dielectric constant.

15. The 3D semiconductor memory device of claim 14, wherein each of the first pattern and the second pattern comprises at least one of doped aluminum nitride, doped zinc oxide, two-dimensional ferroelectric materials, or a laminated structure, in which ferroelectric layers and low-k dielectric layers are stacked.

16. The 3D semiconductor memory device of claim 14, wherein one of the first pattern and the second pattern comprises a ferroelectric material, and
wherein the other of the first pattern and the second pattern comprises an antiferroelectric material or a low-k dielectric material.

17. The 3D semiconductor memory device of claim 14, wherein the ferroelectric pattern further comprises a third pattern between the second pattern and the semiconductor pattern, and
wherein the second pattern comprises a material having a third dielectric constant that is lower than the first dielectric constant of the first pattern and the second dielectric constant of the second pattern.

18. The 3D semiconductor memory device of claim 17, wherein each of the first pattern, the second pattern, and the third pattern comprises at least one of doped aluminum nitride, doped zinc oxide, two-dimensional ferroelectric materials, or a laminated structure, in which ferroelectric layers and low-k dielectric layers are stacked.

19. The 3D semiconductor memory device of claim 17, wherein each of the first pattern and the third pattern comprises a ferroelectric material, and
wherein the second pattern comprises an anti-ferroelectric material or a low-k dielectric material.

20. The 3D semiconductor memory device of claim 12, wherein the data storage pattern further comprises a channel insulating layer between the ferroelectric pattern and the semiconductor pattern or a gate insulating layer between each of the gate electrodes and the ferroelectric pattern.
